(19) United States
(12) Patent Application Publication
(10) Pub. No.: US 2011/0227199 A1
(43) Pub. Date: Sep. 22, 2011

(54) METHOD FOR PRODUCING SEMICONDUCTOR SUBSTRATE, SEMICONDUCTOR SUBSTRATE, METHOD FOR MANUFACTURING ELECTRONIC DEVICE, AND REACTION APPARATUS

(75) Inventors: Masahiko Hata, Tsuchiura-shi (JP); Tomoyuki Takada, Tsukuba-shi (JP); Hisashi Yamada, Tsukuba-shi (JP)

(73) Assignee: SUMITOMO CHEMICAL COMPANY, LIMITED, Chuo-ku, Tokyo (JP)

(21) Appl. No.: 13/131,513

(22) PCT Filed: Nov. 26, 2009
(86) PCT No.: PCT/JP2009/006403

§ 371 Date: May 26, 2011

(30) Foreign Application Priority Data
Nov. 28, 2008 (JP) 2008-305612

(51) Int. Cl. H01L 29/02; H01L 21/20; H05B 6/10

(52) U.S. Cl. 257/616; 438/478; 438/479; 219/647; 257/659; 257/E21.09; 257/E29.002

(57) ABSTRACT

There is provided a method of producing a semiconductor wafer by thermally processing a base wafer having a portion to be thermally processed that has a single-crystal layer and is to be subjected to thermal processing and a portion to be protected that is to be protected from heal, to be added during the thermal processing. The method comprises a step of forming, above the portion to be protected, a protective layer for protecting the portion to be protected from an electromagnetic wave to be applied to the base wafer, and a step of annealing the portion to be thermally processed, by applying the electromagnetic wave to the entire base wafer.

### TECHNICAL FIELD

The present invention relates to a method of producing a semiconductor wafer, a semiconductor wafer, a method of producing an electronic device, and a reaction apparatus.

### BACKGROUND ART

In recent years, a variety of highly advanced electronic devices using a compound semiconductor such as GaAs in an active region have been developed. Crystallinity of the compound semiconductor has a great impact on the performance of the electronic device, and so it is required to form a compound semiconductor having superior crystallinity. For example, when an electronic device using a GaAs-based compound semiconductor in an active region is manufactured, a crystalline thin film is epitaxially grown on a GaAs wafer, or a Ge wafer that can have a lattice match with the compound semiconductor to achieve a crystalline thin film having high quality.

For example, Patent Document 1 discloses a compound semiconductor epitaxial wafer and a compound semiconductor device in which a GaAs wafer, an AlGaAs buffer layer, a GaAs channel layer, and a GaAs contact layer are arranged in the stated order. The crystalline thin films made of the compound semiconductors are formed by vapor-phase epitaxy.

Non-Patent Document 1 discloses that the crystallinity of a Ge crystalline thin film having been epitaxially grown on a Si wafer (base wafer) can be improved by performing cycle thermal annealing on the Ge crystalline thin film. For example, a Ge crystalline thin film having an average dislocation density of 2.3×10⁶ cm⁻² can be yielded by performing thermal annealing at the temperature of 800° C. to 900° C. Here, the average dislocation density is introduced as an exemplary lattice defect density.

Patent Document 1: JP 11-345812 A

Non-Patent Document 1: Hsin-Chino Luan Ct al., “High-quality Ge epilayers on Si with low threading-dislocation densities,” APPLIED PHYSICS LETTERS, VOLUME 75, NUMBER 19, 8 Nov. 1999

### SUMMARY OF THE INVENTION

### Problem to be Solved by the Invention

Crystallinity of a channel layer can be improved by forming a GaAs-based compound semiconductor by crystal growth on a GaAs wafer or a Ge wafer. This, however, increases the manufacturing cost of the electronic device since the GaAs wafer, the Ge wafer and the like are more expensive than a Si wafer. In addition, since the GaAs wafer and the Ge wafer do not have sufficiently high heat dissipation characteristics, limitations are imposed on the density of the devices to be formed or a working temperature of the devices. For the above-discussed reasons are desired a semiconductor wafer and an electronic device that have a good-quality compound semiconductor crystalline thin film in which a wafer being inexpensive and having superior heat dissipation characteristics such as a Si wafer has been used.

The crystallinity of a Ge thin film having been formed on a Si wafer can be improved by annealing the Ge thin film at the temperature of 800° C. to 900° C. The annealing, however, cannot be performed at the temperature of 800° C. to 900° C. when the wafer has a low-thermal-resistance portion. In other wards, when applying such a method to the production of the electronic device, the electronic device production process is significantly restricted. In addition, a thermal design of the electronic device will be very complex.

### Means for Solving Problem

For a solution to the above-mentioned problem, according to the first aspect related to the present invention, provided is one exemplary method of producing a semiconductor wafer by thermally processing a base wafer having a portion to be thermally processed that has a single-crystal layer and is to be subjected to a thermal processing and a portion to be protected that is to be protected from heat to be added during the thermal processing. The method of producing a semiconductor wafer includes a step of forming, above the portion to be protected, a protective layer for protecting the portion to be protected from an electromagnetic wave to be applied to the base wafer, and a step of annealing the portion to be thermally processed, by applying the electromagnetic wave to the portion to be thermally processed and the portion to be protected of the base wafer. The production method further includes, for example, a step of forming, as the portion to be protected, an electronic element in the base wafer. Here, the electronic element includes a silicon device. A step of forming, as the portion to be protected, an active region of an electronic element in the base wafer can be further included. For example, the base wafer is any one of a Si wafer, an SOI wafer, a Ge wafer, a GOI wafer, and a GaAs wafer.

A step of forming a metal interconnection as the portion to be protected can be further included prior to the step of forming a protective layer. Here, in the step of forming a protective layer, the protective layer is formed above the metal interconnection. The step of Forming a metal interconnection includes, for example, forming a plurality of metal interconnections and an insulating film that insulates between the metal interconnections from each other. The metal interconnection is, for example, Al. In the step or annealing, a temperature of the metal interconnection is preferably maintained at or lower than 650° C.

A step of forming, in the base wafer, the portion to be thermally processed including a SiₓGe₁₋ₓ crystal (0≦x<1) can be further included. In this case, for example, a step of forming, by crystal growth, a group III-V compound semiconductor that has a lattice match or a pseudo lattice match with the SiₓGe₁₋ₓ crystal (0≦x<1) can be included after the step of annealing. In the step of annealing, the portion to be thermally processed can be annealed without exposing the base wafer to air after the step of forming a portion to be thermally processed. Furthermore, the step of forming a portion to be thermally processed and the step of annealing can be performed within a same reaction chamber. In the step of forming a group III-V compound semiconductor by crystal growth, the electromagnetic wave can be applied again to the base wafer by using the light source that applied the electromagnetic wave in the step of annealing.

In the step of annealing, the electromagnetic wave can be uniformly applied to the entire base wafer. In the step of annealing, for example, the electromagnetic wave that has been pulsed is applied to the base wafer multiple times. In the step of annealing, the lattice defect density of the SiₓGe₁₋ₓ crystal (0≦x<1) is reduced to, for example, 10⁵ cm⁻² or lower. The electromagnetic wave can be applied from a side of the main plane of the base wafer while heating is performed from a side of the back plane being opposite to the main plane of the base wafer in which the portion to be thermally processed has been provided.

The step of forming a protective layer can include a step of forming, on the base wafer, an inhibition layer that inhibits a precursor of the portion to be thermally processed from growing into a crystal and protects the portion to be protected from the electromagnetic wave to be applied to the base wafer, and forming, in the inhibition layer, an opening that penetrates the inhibition layer to the base wafer, and a step of forming, as the portion to be thermally processed, a seed crystal within the opening, and in the step of annealing, the seed crystal can also be annealed by applying the electromagnetic wave. The step of forming a protective layer can include further forming, on the inhibition layer, a block layer that blocks at least part of the electromagnetic wave.

For example, a step of forming, by crystal growth, a compound semiconductor that has a lattice match or a pseudo lattice match with the seed crystal is included after the step of annealing. For example, the seed crystal is a SiₓGe₁₋ₓ crystal (0≦x<1), and the compound semiconductor is a group III-V compound semiconductor.

The protective layer, for example, has a higher reflectivity of the electromagnetic wave than the portion to be protected. The protective layer can include a thermal conduction restraining layer that restrains thermal conduction, and a block layer that has been disposed on the thermal conduction restraining layer and has a higher reflectivity of the electromagnetic wave than the thermal conduction restraining layer, and the thermal conduction restraining layer can have a lower thermal conductivity than the block layer. The thermal conduction restraining layer preferably has a lower thermal conductivity than the portion to be protected.

The thermal conduction restraining layer includes any one of silicon oxide, silicon nitride, silicon oxynitride, aluminum oxide, and polyimide. The block layer includes, for example, a reflective layer that reflects at least part of the electromagnetic wave. The block layer can include a scattering layer that scatters at least part of the electromagnetic wave. The block layer can include an absorptive layer that absorbs at least part of the electromagnetic wave. The absorptive layer has a higher absorption coefficient of the electromagnetic wave than the portion to be thermally processed.

According to the second aspect related to the present invention, provided is one exemplary semiconductor wafer including a base wafer, an electronic element that has been formed on the base wafer and has an active region, a SiₓGe₁₋ₓ crystal (0≦x<1) disposed on the base wafer, and a protective layer that covers the active region and protects the active region from an electromagnetic wave to be applied to the base wafer. The semiconductor wafer can further include an inhibition layer that has been formed on the electronic element and inhibits a precursor of the SiₓGe₁₋ₓ crystal from growing into a crystal and serves as the protective layer, and the SiₓGe₁₋ₓ crystal (0≦x<1) can be disposed within an opening that penetrates the inhibition layer to the base wafer. A block layer that has been disposed on the inhibition layer and blocks at least part of the electromagnetic wave can further be included.

According to the third aspect related to the present invention, provided is one exemplary method of producing an electronic device having a first electronic element and a second electronic element. The method of producing an electronic device includes a step of forming the first electronic element on a base wafer, a step of forming a protective layer that protects the first electronic element from an electromagnetic wave to be applied to the base wafer, a step of forming a SiₓGe₁₋ₓ crystal (0≦x<1) on the base wafer, a step of annealing the SiₓGe₁₋ₓ crystal by applying the electromagnetic wave to the base wafer, a step of forming, by crystal growth, a group III-V compound semiconductor that has a lattice match or a pseudo lattice match with the SiₓGe₁₋ₓ crystal, and a step of forming, On the group III-V compound semiconductor, the second electronic element that is electrically connected to the first electronic element.

The method of producing an electronic device can further include a step of forming, so as to cover at least the first electronic element, an inhibition layer that inhibits a precursor of the SiₓGe₁₋ₓ crystal from growing into a crystal and protects the first electronic element from the electronic wave, a step of forming an opening in a region of the inhibition layer, the region being other than a region covering the first electronic element, the opening penetrating the inhibition layer to the base wafer, and a step of forming the SiₓGe₁₋ₓ crystal within the opening by growing the precursor of the SiₓGe₁₋ₓ crystal into a crystal. A step of forming a block layer that blocks the electromagnetic wave on the region of the inhibition layer, the region covering the first electronic element, can be further included.

For example, the first electronic element is an electronic element included in at least one circuit among a driving circuit for the second electronic element, a correction circuit for improving linearity of input and output characteristics of the second electronic element, and a protection circuit for an input stage of the second electronic element, and the second electronic element is an electronic element included in at least one device among an analog electronic device, a light emitting device, and a light receiving device.

According to the fourth aspect related to the present invention, provided is one exemplary reaction apparatus including a reaction chamber holding therein a base wafer having a portion to be thermally processed that has a single-crystal layer and is to be subjected to a thermal processing and a portion to be protected that is to be protected from heat to be added during the thermal processing, an irradiating section that applies an electromagnetic wave toward the main plane of the base wafer, the main plane having the portion to be protected and the portion to be thermally processed that are formed therein, a heating section that heats the entire base wafer from a side of the back plane that is opposite to the main plane, a heating temperature measuring section that measures a temperature of the base wafer, a temperature measuring section that measures a temperature of the portion to be protected and a temperature of the portion to be thermally processed, and a control section that controls the irradiating section and the heating section based on a result of the measurement performed by the heating temperature measuring section and a result of the measurement performed by the temperature measuring section.

The temperature measuring section measures the temperature of the portion to be protected and the temperature of the portion to be thermally processed, for example, based on radiant heat from the portion to be protected and radiant heat from the portion to be thermally processed. The temperature measuring section can sequentially measure the temperature of the portion to be protected and the temperature of the portion to be thermally processed.

For example, the control section determines, based on a result of the measurement performed by the heating temperature measuring section, an application period during which the irradiating section applies the electromagnetic wave and a non-application period during which the irradiating section does not apply the electromagnetic wave. A filter that has been disposed between the base wafer and the irradiating section and blocks a wavelength component of the electromagnetic wave at which the absorption coefficient in the portion to be protected is higher than the absorption coefficient in the portion to be thermally processed, can be further included.

The reaction apparatus further includes, for example, a gas supply section that supplies a source gas into the reaction chamber, and a compound semiconductor is formed by crystal growth on the portion to be thermally processed, by reaction of the source gas within the reaction chamber. In the reaction apparatus, a temperature of the source gas and a temperature of a carrier gas that is supplied along with the source gas can be lower than a temperature of the base wafer, and the source gas can cool the base wafer while the compound semiconductor is formed by crystal growth.

### BRIEF DESCRIPTION OF THE DRAWINGS

FIG. 1 schematically illustrates an exemplary cross-section of a semiconductor wafer 110.

FIG. 2 schematically illustrates an exemplary cross-section of a semiconductor wafer 210.

FIG. 3 shows, as an example, how the temperature of the front plane of a thermal conduction restraining layer 254 and the temperature of the hack plane of the thermal conduction restraining layer 254 vary.

FIG. 4 schematically illustrates an exemplary cross-section of a semiconductor wafer 410.

FIG. 5 schematically illustrates an exemplary cross-section of an electronic device 500.

FIG. 6 is a flow chart to illustrate an exemplary method of producing the electronic device 500.

FIG. 7 schematically illustrates an exemplary cross-section observed during the production process of a semiconductor wafer 510.

FIG. 8 schematically illustrates an exemplary cross-section observed during the production process of the semiconductor wafer 510.

FIG. 9 schematically illustrates an exemplary semiconductor wafer 910 observed during the production process of the semiconductor wafer 510.

FIG. 10 schematically illustrates the exemplary semiconductor wafer 910 observed during the production process of the semiconductor wafer 510.

FIG. 11 schematically illustrates an exemplary cross-section of the semiconductor wafer 510.

FIG. 12 schematically illustrates an exemplary cross-section of a thermal process apparatus 1200.

FIG. 13 schematically illustrates an exemplary cross-section of the semiconductor wafer 110.

FIG. 14 schematically illustrates the exemplary semiconductor wafer 910 observed during the production process of the semiconductor wafer 510.

FIG. 15 is a TEM photograph showing the cross-section of the semiconductor wafer 910, which has been taken out of a thermal process furnace 1210.

FIG. 16 is a TEM photograph showing the cross-section of the semiconductor wafer 910 including a SiₓGe₁₋ₓ crystal 2000, which has not been thermally processed.

FIG. 17 shows how the collector current of a HBT varies depending on the collector voltage of the HBT.

FIG. 18 shows experimental data to determine a maximum oscillation frequency that produces a current gain of 1.

FIG. 19 shows how the growth rate of a group III-V compound semiconductor 566 is dependent on the size of a covering region and the size of an opening 556.

### MODE FOR CARRYING OUT THE INVENTION

Some aspects of the invention will now be described based on the embodiments, which do not intend to limit the scope of the present invention, but exemplify the invention. All of the features and the combinations thereof described in the embodiment are not necessarily essential to the invention. The embodiments of the present invention will be hereinafter described with reference to the appended drawings, in which identical or similar components may be designated by identical reference numerals and not be repeatedly described. It should be noted that the drawings are only schematic, and the relation between the thickness and the planar dimension, the ratio and other dimensional features shown in the drawings may not reflect the actual scale. For the purposes of the description, the dimensions or ratios may be partly on different scales among the drawings.

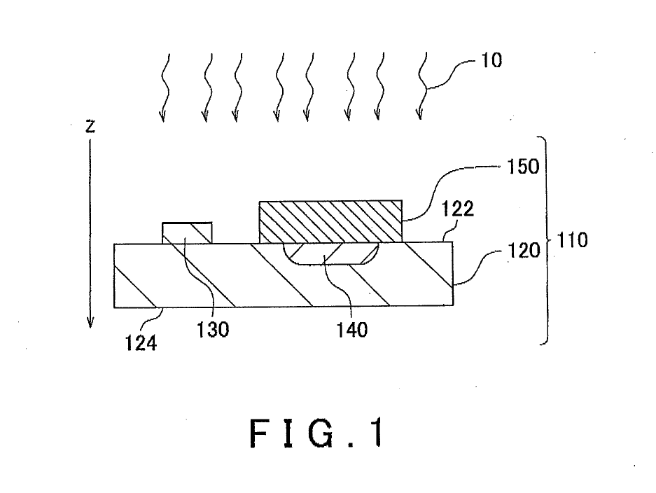

FIG. 1 schematically illustrates an exemplary cross-section of a semiconductor wafer 110. The semiconductor wafer 110 is produced by thermally processing a base wafer 120. The base wafer 120 has a first main plane 122 and a second main plane 124. The base wafer 120 has a portion to be thermally processed 130 and a portion to be protected 140. The portion to be thermally processed 130 has a single-crystal layer and is to be subjected to a thermal processing. The portion to be protected 140 is to be protected from the heat to be added during the thermal processing. The portion to be thermally processed 130 is disposed on the first main plane. The portion to be protected 140 is, for example, disposed, on the first main plane 122, in a region other than the region in which the portion to be thermally processed 130 is disposed.

To produce the semiconductor wafer 110, after a protective layer 150 is provided above the portion to be protected 140, an electromagnetic wave is applied to a region of the base wafer 120, the region including the portion to be thermally processed 130 and the portion to be protected 140. For example, the electromagnetic wave is applied to the entire front plane of the base wafer 120. The protective layer 150 protects the portion to be protected 140 from an electromagnetic wave 10 that is to be applied to the base wafer 120 Thus, the portion to be thermally processed 130 is selectively heated. In other words, by selectively heating the portion to be thermally processed 130, only the portion to be thermally processed 130 can be selectively annealed among the portion to be thermally processed 130 and the portion to be protected 140 during the production of the semiconductor wafer 110.

Here, “selectively heating” means that a particular region on the base wafer 120 may receive more heat than the other region. As used herein, the expression “above A” indicates any position on the line that originates at “A” and extends toward the application source of the electromagnetic wave 10 applied to the portion to be thermally processed 130. The position includes a position on the plane of “A.” Here, “A” is, for example, the base wafer 120, the portion to be thermally processed 130, and the portion to be protected 140.

In other words, the expression “above A” may indicate any position between “A” and the application source that applies the electromagnetic wave 10. More specifically, the protective layer 150 is positioned such that the portion to be protected 140 is sandwiched between the protective layer 150 and the base wafer 120. For example, the expression “above the portion to be protected 140” means any position on the line that originates at the front plane of the portion to be protected 140 and extends in the direction from the second main plane 124 of the base wafer 120 to the first main plane 122.

Likewise, the expression “below A” indicates any position on the line that originates at “A” and extends in the direction opposite to the direction toward the application source of the electromagnetic wave applied to the portion to be thermally processed 130. In other words, the expression “below A” may mean any position on the opposite side, with respect to “A,” to the expression “above A.”

The base wafer 120 is, for example, any one wafer among a Si wafer, a silicon-on-insulator (SOI) wafer, a Ge wafer, a germanium-on-insulator (GOI) wafer, and a GaAs wafer. The Si wafer may be a single-crystal Si wafer. Alternatively, the base wafer 120 may be a sapphire wafer, a glass wafer, or a resin wafer such as a PET film.

When the base wafer 120 is annealed, the portion to be thermally processed 130 is selectively heated. The portion to be thermally processed 130 is a single-crystal semiconductor. The portion to be thermally processed 130 is, for example, formed by chemical vapor deposition (hereinafter, may be referred to as CVD), metal organic chemical vapor deposition (may be referred to as MOCVD), molecular beam epitaxy (may be referred to as MBE), or atomic layer deposition (may be referred to as ALD). The portion to be thermally processed 130 is, for example, a group III-V compound semiconductor or a SiₓGe₁₋ₓ crystal.

The annealing is preferably performed under a composite atmosphere containing hydrogen and an inert gas. If the annealing is performed within air or an inert gas, pits (holes) may be formed on the front plane of the SiₓGe₁₋ₓ crystal. When the annealing is performed under a composite atmosphere containing hydrogen and an inert gas, the hydrogen concentration is preferably 90% or higher of the composite atmosphere, more preferably 95% or higher. The annealing is performed, for example, with a pressure of approximately 20 kPa or lower.

For example, the portion to be thermally processed 130 includes a SiₓGe₁₋ₓ crystal in contact with the first main plane 122 of the base wafer 120. Here, x is a real number satisfying the condition of 0≦x<1. For example, a layer of a Si crystal or the like may be provided between the base wafer and the SiₓGe₁₋ₓ crystal. Due to the difference in lattice constant between the base wafer 120 and the SiₓGe₁₋ₓ crystal, and other factors, defects such as lattice defects may occur within the SiₓGe₁₋ₓ crystal. The annealing of the SiₓGe₁₋ₓ crystal by means of heating causes the defects to move within the SiₓGe₁₋ₓ crystal, so that the defects are trapped by the boundary or the front planes of the SiₓGe₁₋ₓ crystal, an internal gettering sink of the SiₓGe₁₋ₓ crystal, or the like. As a result, the SiₓGe₁₋ₓ crystal can have a region with a reduced density of defects represented by threading dislocations that reach the front plane of the SiₓGe₁₋ₓ crystal and thus achieve high quality.

For example, the SiₓGe₁₋ₓ crystal has a defect trap for trapping defects, which move within the crystal. For example, the defect trap is positioned such that the maximum distance between from any point within the SiₓGe₁₋ₓ crystal to the defect trap is equal to or shorter than the distance by which defects can move when the annealing is performed at a certain temperature and for a certain duration. Here, an example of the defect trap is the boundary of the SiₓGe₁₋ₓ crystal, the boundary between the SiₓGe₁₋ₓ crystal and the side wall of the opening formed in an inhibition layer, or an internal gettering sink of the SiₓGe₁₋ₓ crystal. The SiₓGe₁₋ₓ crystal may be sized such that the maximum width of the SiₓGe₁₋ₓ crystal does not exceed double the distance by which the defects can move when the annealing is performed at a certain temperature and for a certain duration.

The portion to be thermally processed 130 may be a portion of the base wafer. For example, when the base wafer 120 is a Ge wafer or a GOI wafer, the portion to be thermally processed 130 is at least a portion of the SiₓGe₁₋ₓ crystal layer (0≦x<1) included in the Ge wafer or the GOI wafer. In this case, the base wafer 120 may have a heat retaining portion that at least partially surrounds the portion to be thermally processed 130. The heat retaining portion is preferably made of a material with a low thermal conductivity. In this way, the energy of the electromagnetic wave 10 applied to the portion to be thermally processed 130 is efficiently used.

The portion to be thermally processed 130 may be a region that is to constitute an impurity region of a semiconductor device. For example, the portion to be thermally processed 130 is an impurity implanted region into which impurities have been introduced by ion implantation or other techniques. In this case, impurities are introduced by ion implantation or other techniques, for example, into at least a portion of a region that is to constitute the impurity implanted region. After this, the region is heated to be annealed, so that the crystallinity of the region is restored and the impurities are activated. In this way, the impurity implanted region is formed.

Alternatively, the portion to be thermally processed 130 may be an impurity diffused region in which impurities have been diffused by a thermal processing. In this case, an impurity diffusing source is formed, for example, by coating, CVD or other techniques in at least a portion of a region that is to constitute the impurity diffused region. After this, the region is heated to be annealed. In this way, the impurity diffused region is formed.

The impurity region is, for example, a well, a source region, or a drain region of a metal-insulator-semiconductor field-effect transistor (MISFET). The MISFET may be a metal-oxide-semiconductor field-effect transistor (MOSFET).

The portion to be protected 140 is protected by the protective layer 150 from the electromagnetic wave 10 applied to the base wafer 120. Specifically speaking, the portion to be protected 140 is maintained at a lower temperature than a maximum reachable temperature or the portion to be thermally processed 130, when the electromagnetic wave 10 is applied to the entire Front plane of the base wafer 120. The portion to be protected 140 is positioned in or on a portion of the base wafer 120, the portion being other than a portion in or on which the portion to be thermally processed 130 is positioned. For example, the portion to be protected 140 is formed in or on the first main plane 122 of the base wafer 120.

The portion to be protected 140 includes a region with a lower thermal resistance than the portion to be thermally processed 130. For example, the portion to be protected 140 includes a region the characteristics of which exceed an allowable range at a lower temperature than the portion to be thermally processed 130. In the portion to be protected 140, for example, an electronic element such as a Si semiconductor element or a group III-V compound semiconductor element, or a portion of the electronic element is formed.

The portion to be protected 140 includes, for example, an active region of an electronic element to be formed in the semiconductor wafer 110. The electronic element is, for example, an active element included in a semiconductor device such as a MOSFET, a MISFET, a heterojunction bipolar transistor (HBT) and a high electron mobility transistor (HEMT), a light emitting device such as a semiconductor laser, a light emitting diode, and a light emitting thyristor, a light receiving device such as a photodiode and an optical sensor, or a device such as a solar cell. The active region of the electronic element is, for example, the channel region of a field-effect transistor, the base-emitter junction region of a bipolar transistor, or the anode-cathode junction region of a diode. The electronic element may be a passive element such as a resistor, a capacitor, or an inductor.

The portion to be protected 140 may include a semiconductor and a dielectric that are in contact with each other. The boundary between the semiconductor and the dielectric is, for example, used as the MOS gate boundary formed in the active region of the MOSFET. The MOS gate boundary has a low thermal resistance. Accordingly, the characteristics of the MOSFET may be degraded if the MOS gate boundary is exposed to a high temperature for a long period of time. Thus, the MOS gate boundary is preferably protected from the electromagnetic wave 10.

The portion to be protected 140 may include a highly impurity-doped epitaxially grown layer, or an impurity region of a semiconductor device. The impurity region is, for example, the above-described impurity implanted region or impurity diffused region. The impurity region or the epitaxially grown layer is, for example, the well the source region, or the drain region of a MISFET such as a MOSFET.

The impurity region and the epitaxially grown layer experience changes in characteristics when heated. For example, the impurities included in the impurity diffused region are diffused by heating. The semiconductor device requires a complicated thermal design if the impurity region and the epitaxially grown layer are exposed to a high temperature after formed. Therefore, the impurity region and the epitaxially grown layer are preferably protected from the electromagnetic wave 10.

The portion to be protected 140 may include a metal interconnection. After a metal interconnection is formed as at least a portion of the portion to be protected 140, the protective layer 150 may be provided above the metal interconnection. The protective layer 150 serves to maintain the temperature of the metal interconnection lower than the melting point of the metal interconnection. For example, when the metal interconnection contains Al, the melting point of which is 660° C., the protective layer 150 preferably maintains the temperature of the metal interconnection, for example, at or lower than 650° C. The metal interconnection may be connected to an electronic element to be formed in the base wafer 120.

The portion to be protected 140 may have a plurality of metal interconnections formed therein. The portion to be protected 140 preferably has one or more insulating films that insulate the metal interconnections from each other. The insulating films are, for example, made of polyimide. When the insulating films are made of polyimide, the protective layer 150 preferably maintains the temperature of the insulating films, for example, at or lower than 500° C.

The protective layer 150 protects the portion to be protected 140 from the electromagnetic wave 10. The protective layer 150 protects the portion to be protected 140, for example, by attenuating the intensity of the electromagnetic wave 10 that reaches the portion to be protected 140. Alternatively, the protective layer 150 protects the portion to be protected 140, for example, by preventing the heat that is generated by the protective layer 150 when the protective layer 150 absorbs the electromagnetic wave 10 from being conducted to the portion to be protected 140.

The protective layer 150 is positioned in such a manner that the protective layer 150 and the portion to be protected 140 are arranged in the stated order in the transmission direction Z of the electromagnetic wave 10. The transmission direction Z extends from the first main plane 122 of the base wafer 120 to the second main plane 124, and is substantially perpendicular to the first main plane 122. The electromagnetic wave 10 may be applied in a direction other than the transmission direction Z.

As used herein, “a substantially perpendicular direction” refers not only to a strictly perpendicular direction but also to directions slightly off the perpendicular direction considering the manufacturing errors of the wafer and the respective components. Referring to the phrase “transmission direction Z,” the term “transmission” is used in order to identify a particular direction and does not require that the electromagnetic wave 10 actually transmit. For example, a case is included where the electromagnetic wave 10 is blocked by the protective layer 150.

The protective layer 150 attenuates the intensity of the electromagnetic wave that reaches the portion to be protected 140, for example, by blocking at least a part of the electromagnetic wave 10. The protective layer 150 may attenuate the intensity of the electromagnetic wave 10 that reaches the portion to be protected 140, by reflecting, scattering, or absorbing at least a part of the electromagnetic wave 10. In this manner, the protective layer 150 protects the portion to be protected 140 from the electromagnetic wave 10. Thus, even if the electromagnetic wave 10 is applied to the portion to be thermally processed 130 and the portion to be protected 140, the maximum reachable temperature of the portion to be protected 140 is maintained lower than the maximum reachable temperature of the portion to be thermally processed 130. Stated differently, the portion to be thermally processed 130 can be selectively heated even when the electromagnetic wave 10 simultaneously heats a large area of the base wafer 120, for example, when the base wafer 120 is subjected to flash annealing.

The protective layer 150 includes a metal thin film made of, for example, Ag, Au, Al or the like. In this way, the protective layer 150 can reflect at least a part of the electromagnetic wave 10. The protective layer 150 may include a resin layer containing fine particles, or a layer constituted by dielectrics having different refractive indices in which fine particles are diffused. In this way, the protective layer 150 can scatter at least a part of the electromagnetic wave 10. The protective layer 150 may include amorphous silicon. In this way, the protective layer 150 can absorb at least a part of the electromagnetic wave 10. The protective layer 150 may include a plurality of layers that are respectively made of different materials.

The electromagnetic wave 10 is applied to the base wafer 120 in order to reduce the average dislocation density of the portion to be thermally processed 130. The electromagnetic wave 10 may have a wavelength at which the absorption coefficient of the portion to be thermally processed 130 peaks for the electromagnetic wave 10. Alternatively, the electromagnetic wave 10 may have a wavelength at which a part of the electromagnetic wave 10 transmits through the portion to be protected 140 without being absorbed by the portion to be protected 140. By selecting the wavelength of the electromagnetic wave 10 in the above-discussed manner, the portion to be thermally processed 130 can be selectively heated even if the electromagnetic wave 10 is directly applied to the portion to be thermally processed 130 and the portion to be protected 140.

For example, at the wavelength of the electromagnetic wave 10 applied, the portion to be thermally processed 130 has a higher absorption coefficient or the electromagnetic wave 10 than the portion to be protected 140. Specifically speaking, the electromagnetic wave 10 is light having a wavelength or no shorter than 1200 nm and no longer than 1800 nm. The light is absorbed by the SiₓGe₁₋ₓ crystal (0≦x<1), but not absorbed by and transmits through the Si crystal. In this manner, the SiₓGe₁₋ₓ crystal (0≦x<1) can be selectively heated while the Si device can be prevented from being thermally damaged.

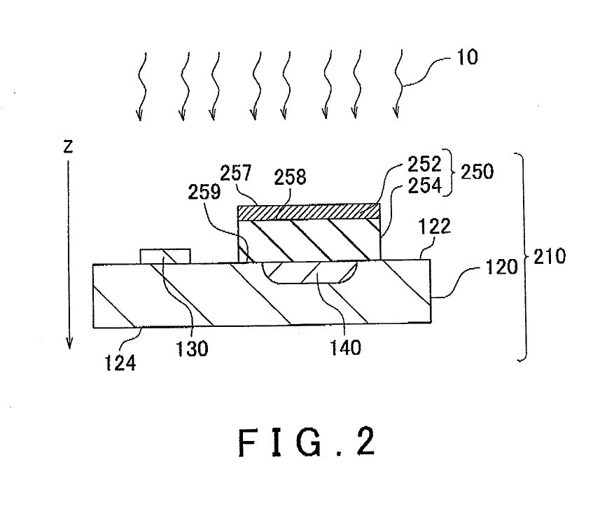

FIG. 2 schematically illustrates an exemplary cross-section of a semiconductor wafer 210. The semiconductor wafer 210 has a protective layer 250 in place of the protective layer 150 or the semiconductor wafer 110 shown in FIG. 1. The protective layer 250 includes a block layer 252 and a thermal conduction restraining layer 254. The block layer 252, the thermal conduction restraining layer 254, and the portion to be protected 140 are arranged in the stated order in the transmission direction Z of the electromagnetic wave 10. The semiconductor wafer 210 has the same configuration and is produced in the same manner as the semiconductor wafer 110, except that the semiconductor wafer 210 has the protective layer 250 in place of the protective layer 150. Therefore, only the protective layer 250 is described in the following.

The block layer 252 blocks at least a part of the electromagnetic wave 10. The block layer 252 includes, for example, a reflective layer that reflects at least a part of the electromagnetic wave 10. The block layer 252 preferably has a higher reflectivity of the electromagnetic wave 10 than the portion to be protected 140.

The reflective layer may include a metal thin film. The metal thin film is, for example, a thin film containing a metal such as Ag, Au, or Al. The reflective layer can be formed, for example, by vacuum evaporation. The block layer 252 may be made of a plurality of materials. The block layer 252 includes, for example, a silicon oxide layer, a silicon nitride layer, a silicon oxynitride layer, an aluminum oxide layer, or any combination thereof. The metal thin film may be embedded within any of the above-mentioned layers.

The block layer 252 may include a scattering layer that scatters at least a part of the electromagnetic wave 10. The scattering layer includes, for example, a resin layer containing fine particles, or a layer constituted by dielectrics having different refractive indices in which fine particles are diffused. The scattering layer can be formed, for example, by coating. The fine particles may be transparent ceramic fine particles, for example, colloidal silica. The fine particles may be embedded within a silicon oxide layer, a silicon nitride layer, a silicon oxynitride layer, an aluminum oxide layer, or any combination thereof.

The scattering layer scatters at least a part of the electromagnetic wave 10 that enters the block layer 252 to change the travel direction of the electromagnetic wave 10. This increases the travel distance of the electromagnetic wave 10 within the block layer 252 so that the block layer 252 absorbs more of the electromagnetic wave 10.

The block layer 252 may include an absorptive layer that absorbs at least a part of the electromagnetic wave 10 to convert the absorbed electromagnetic wave 10 into thermal energy or the like. The absorptive layer preferably has a higher absorption coefficient of the electromagnetic wave 10 than the portion to be thermally processed 130. The absorptive layer may contain an absorber such as amorphous silicon or germanium. The absorptive layer can be formed, for example, by CVD. The absorber may be embedded within a silicon oxide layer, a silicon nitride layer, a silicon oxynitride layer, an aluminum oxide layer, or any combination thereof.

The block layer 252 preferably releases the heat generated by the scattering layer and the absorptive layer when these layers absorb the electromagnetic wave 10, through thermal irradiation from the front plane and the lateral plane of the block layer 252 and through the thermal conduction to the air flow within the space in contact with the front plane of the block layer 252. By employing the above configurations, the block layer 252 can block at least a part of the electromagnetic wave 10. As a result, the protective layer 250 can protect the portion to be protected 140 from the electromagnetic wave 10. Note that the block layer 252 may include more than one of the reflective layer, the scattering layer, and the absorptive layer.

The thermal conduction restraining layer 254 is positioned between the block layer 252 and the portion to be protected 140. The thermal conduction restraining layer 254 restrains the heat generated by the block layer 252 as a result of the application of the electromagnetic wave 10 from reaching the portion to be protected 140.

The thermal conduction of the thermal energy generated by the block layer 252 is partially restrained by the contact thermal resistance between the block layer 252 and the thermal conduction restraining layer 254. While the heat generated in the block layer 252 is transferred through the thermal conduction restraining layer 254, a non-uniform temperature distribution occurs within the thermal conduction restraining layer 254. As a result, the maximum reachable temperature becomes lower in the order of the front plane 257 of the block layer 252, the front plane 258 of the thermal conduction restraining layer 254, and the back plane 259 of the thermal conduction restraining layer 254. The thermal conduction restraining layer 254 preferably has a lower thermal conductivity than the block layer 252. Furthermore, the thermal conductivity of the thermal conduction restraining layer 254 is preferably lower than the thermal conductivity of the portion to be thermally processed 130.

The second main plane 124 of the base wafer 120 is preferably maintained at a lower temperature than the front plane 257 of the block layer 252. This can cause a non-uniform temperature distribution to occur within the thermal conduction restraining layer 254, so that the maximum reachable temperature at the back plane 259 of the thermal conduction restraining layer 254 can be lowered.

The thermal conduction restraining layer 254 may include silicon oxide, silicon nitride, silicon oxynitride, aluminum oxide, or a thermally-resistant resin such as polyimide. The thermal conduction restraining layer 254 may be constituted by a plurality of layers. Specifically speaking, the thermal conduction restraining layer 254 may include a thermally insulating layer that is in contact with the portion to be protected 140. Furthermore, the thermal conduction restraining layer 254 may release the heat generated as a result of the application of the electromagnetic wave 10 by guiding the generated heat to a plane other than the plane in contact with the portion to be protected 140 through a heat transfer path made of a highly thermally conductive material.

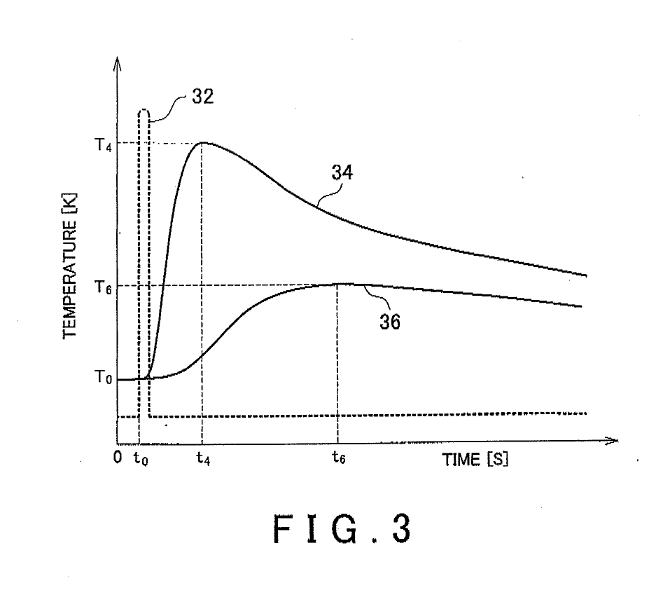

FIG. 3 shows, as an example, how the temperature of the front plane 258 of the thermal conduction restraining layer 254 and the temperature of the back plane 259 of the thermal conduction restraining layer 254 vary. In the drawing, the horizontal axis and the vertical axis respectively represent the time and the temperature. In the example shown in FIG. 3, the absorptive layer that is adapted to absorb the electromagnetic wave 10 is used as the block layer 252. FIG. 3 shows how the temperatures vary in a case where the base wafer 120 is preheated and the second main plane 124 is maintained at a lower temperature than the front plane 258.

At a timing t0, the electromagnetic wave 10 that has been pulsed is applied to the base wafer 120 as shown by a dotted line 32. As a result of the application, the temperature of the front plane 258 of the thermal conduction restraining layer 254 rapidly increases. The heat is then conducted in the Z direction, so that a certain thermal flow occurs from the front plane 258 to the back plane 259. A solid line 34 shows, as an example, how the temperature of the front plane 258 of the thermal conduction restraining layer 254 varies over time. A solid line 36 shows, as an example, how the temperature of the hack plane 259 of the thermal conduction restraining layer 254 varies over time.

As shown by the solid lines 34 and 36, the front plane 258 and the back plane 259 have the same temperature of approximately T0 at the timing t0. As the electromagnetic wave 10 is applied, the temperature of the front plane 257 of the block layer 252 instantaneously rises. The heat generated in the block layer 252 reaches the front plane 258 of the thermal conduction restraining layer 254.

As shown by the solid line 34, the temperature of the front plane 258 of the thermal conduction restraining layer 254 starts rising some time after the timing t0. After this, the temperature reaches the maximum reachable temperature T4 at a timing t4 and then starts falling gradually. After reaching the front plane 258 of the thermal conduction restraining layer 254, the heat is conducted inside the thermal conduction restraining layer 254 to reach the back plane 259 of the thermal conduction restraining layer 254. As shown by the solid line 36, the temperature of the back plane 259 of the thermal conduction restraining layer 254 starts rising after the temperature of the front plane 258 does, reaches the maximum reachable temperature T6 at a timing t6, and then starts falling gradually.

The maximum reachable temperature T6 of the back plane 259 of the thermal conduction restraining layer 254 is lower than the maximum reachable temperature T4 of the front plane 258 by a number of degrees determined according to the thickness, the thermal conductivity and other parameters of the thermal conduction restraining layer 254. The above indicates that positioning the thermal conduction restraining layer 254 between the block layer 252 and the portion to be protected 140 can protect portion to be protected 140 from the electromagnetic wave 10.

The maximum reachable temperature T6 is given by Equation 1. Equation 1 is a one-dimensional thermal diffusion equation. As seen from Equation 1, the maximum reachable temperature T6 decreases as the thickness of the thermal conduction restraining layer 254 in the Z direction increases. In Equation 1, t denotes the time [s], z denotes the position in terms of the Z direction [m], T denotes the temperature [K] at the position z, and α denotes the thermal diffusivity [m²/s] of the thermal conduction restraining layer 254.

∂T/∂t=α(∂²T/∂²z) Equation 1

The thermal diffusivity α is given by Equation 2. In Equation 2, λ denotes the thermal conductivity of the thermal conduction restraining layer 254 [J/s·m·K], Cp denotes the specific heat at constant pressure of the thermal conduction restraining layer 254 [J/kg·K], and ρ denotes the density of the thermal conduction restraining layer 254 [kg/m³]. Equation 2 indicates that, as the thermal conductivity of the thermal conduction restraining layer 254 decreases, or as the specific heat at constant pressure and the density of the thermal conduction restraining layer 254 increases, the period of time that is required until temperature of the back plane 259 of the thermal conduction restraining layer 254 reaches the maximum reachable temperature T6 increases, or the maximum reachable temperature T6 decreases.

α=λ/(Cρ×ρ) Equation 2

In light of the above, it is preferable that the thermal conduction restraining layer 254 has a lower thermal diffusivity than the portion to be thermally processed 130. It should be noted that the portion to be protected 140 can be also protected even if the thermal diffusivity of the thermal conduction restraining layer 254 is set higher than the thermal diffusivity or the portion to be thermally processed 130. In this case, the maximum reachable temperature T6 or the back plane 259 of the thermal conduction restraining layer 254, which is in contact with the portion to be protected 140, can be still lowered by appropriately adjusting the thickness of the thermal conduction restraining layer 254.

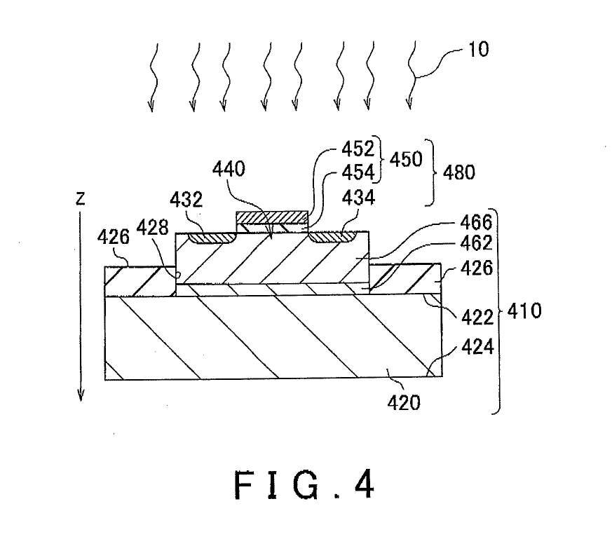

FIG. 4 schematically illustrates an exemplary cross-section of a semiconductor wafer 410. The semiconductor wafer 410 includes a base wafer 420, an inhibition layer 426, a seed crystal 462, a compound semiconductor 466, and a semiconductor device 480.

The base wafer 420 is, for example, any one of a Si wafer, an SOI wafer, a Ge wafer, a GOI wafer, and a GaAs wafer. The base wafer 420 has a first main plane 422 and a second main plane 424.

The semiconductor wafer 410 is produced in the following manner. To begin with, the inhibition layer 426 is formed on the first main plane 422 of the base wafer 420. Subsequently, an opening 428 is formed in the inhibition layer 426. The opening 428 penetrates through the inhibition layer 426 to reach the base wafer 420. Within the opening 428, the seed crystal 462 is disposed.

After this, the compound semiconductor 466 is formed, by crystal growth, on the seed crystal 462. Following this, the semiconductor device 480 is formed on the compound semiconductor 466. The semiconductor device 480 includes, for example, impurity implanted regions 432 and 434, an active region 440, and a protective layer 450. The protective layer 450 includes a gate electrode 452 and a gate insulator 454.

The active region 440 is positioned in the compound semiconductor 466 between the impurity implanted region 432 and the impurity implanted region 434. The active region 440 is equivalent to the portion to be protected 140 described with reference to FIGS. 1 to 3. The regions 432 and 434 are equivalent to the portion to be thermally processed 130 described with reference to FIGS. 1 to 3.

The gate insulator 454 is formed on the active region 440. The gate electrode 452 is formed on the gate insulator 454. The gate electrode 452 and the gate insulator 454 protect the active region 440 from the electromagnetic wave 10. In this manner, the regions 432 and 434 can be selectively heated by applying the electromagnetic wave 10 to the base wafer 420 from above the base wafer 420. The gate electrode 452 serves as the reflective layer, which is one of the examples of the block layer 252 described with reference to FIG. 2. The gate insulator 454 serves as the thermal conduction restraining layer 254 described with reference to FIG. 2.

The inhibition layer 426 inhibits the precursors of the seed crystal 462 and the compound semiconductor 466 from growing into crystals. When the crystal of the compound semiconductor 466 is epitaxially grown by MOCVD, the inhibition layer 426 inhibits the crystal of the compound semiconductor 466 from epitaxially growing on the front plane of the inhibition layer 426.

The inhibition layer 426 is, for example, a silicon oxide layer, an aluminum oxide layer, a silicon nitride layer, a silicon oxynitride layer, a tantalum nitride layer, a titanium nitride layer, or a laminate formed by more than one of the above-mentioned layers. For example, the inhibition layer 426 has the thickness of 0.05 μm to 5 μm. The inhibition layer 426 is in contact with the first main plane 422 of the base wafer 420. The inhibition layer 426 can be formed, for example, by CVD.

The opening 428 penetrates through the inhibition layer 426 in the substantially perpendicular direction to the first main plane 422. The opening 428 externally exposes the first main plane 422. In this way, a crystal can be selectively grown within the opening 428. The opening 428 can be formed, for example, by photolithography such as etching.

The opening 428 has, for example, an aspect ratio of (√3)/3 or higher. When a crystal that is thick to some extent is formed within the opening 428 having an aspect ratio of (√3)/3 or higher, the defects such as lattice defects in the crystal are terminated by the wall of the opening 428. As a result, the front plane of the crystal, the front plane being externally exposed in the opening 428, already has superior crystallinity on completion of the formation of the crystal. The opening 428 may have an area of 1 mm² or smaller, preferably smaller than 0.25 mm².

As used herein, “an aspect ratio of an opening” is defined as a result of dividing “the depth of the opening” by “the width of the opening.” For example, an aspect ratio is defined as the result of dividing the etching depth by the pattern width in “Handbook for Electronics, Information and Communication Engineers, Volume 1,” edited by the Institute of Electronics, Information and Communication Engineers, Page 751, 1988, published by Ohmsha. The term “aspect ratio” is used herein to mean a similar meaning to the above.

The depth of the opening is defined as the depth of the opening in the direction in which the thin films are stacked on the wafer. The width of the opening is defined as the width of the opening in the perpendicular direction to the stacking direction. When the opening has a plurality of widths, the smallest width is used to calculate the aspect ratio of the opening. For example, when the opening is shaped as a rectangle when seen in the stacking direction, the length of the short side of the rectangle is used to calculate the aspect ratio.

The seed crystal 462 provides a seed plane suitable for growing the compound semiconductor 466. The seed crystal 462 prevents the impurities present in the base wafer 420 or the first main plane 422 from adversely affecting the crystallinity of the compound semiconductor 466, The seed crystal 462 is, for example, in contact with the first main plane 422. The seed crystal 462 may include a semiconductor crystal. For example, the seed crystal 462 includes a SiₓGe₁₋ₓ crystal (0≦x<1).

The seed crystal 462 is formed, for example, by epitaxial growth such as CVD. Here, since crystal growth is inhibited on the front plane of the inhibition layer 426, the seed crystal 462 is selectively grown within the opening 428. The seed crystal 462 is preferably subjected to annealing. The annealing can reduce the density of the defects within the seed crystal 462 and thus provide a good seed plane for growing the compound semiconductor 466. The annealing may be performed under the same conditions as the annealing performed on the portion to be thermally processed 130.

The compound semiconductor 466 is formed, for example, in contact with the seed crystal 462 after the seed crystal 462 is annealed. The compound semiconductor 466 has a lattice match or a pseudo lattice match with the seed crystal 462. The compound semiconductor 466 is, for example, a group III-V compound semiconductor such as GaAs. The boundary between the seed crystal 462 and the compound semiconductor 466 may be positioned within the opening 428. The compound semiconductor 466 can be formed, for example, by epitaxial growth such as MOCVD. When the base wafer 420 is a Ge wafer or a GOI wafer, in other words, a wafer the first main plane 422 of which includes a SiₓGe₁₋ₓ crystal (0≦x<1), the compound semiconductor 466 may be formed in contact with the first main plane 422 by using as a seed crystal the SiₓGe₁₋ₓ crystal (0≦x<1).

When the compound semiconductor 466 is GaAs or a semiconductor having a lattice match or a pseudo lattice match with GaAs, x for the SiₓGe₁₋ₓ crystal preferably falls within the range of 0≦x<0.1. More preferably, x=0. When x≦0.1, the difference in lattice constant between the SiₓGe₁₋ₓ crystal and the group III-V compound semiconductor is further reduced and defects are thus unlikely to be generated.

As used herein, the term “a pseudo lattice match” indicates the state in which two semiconductors can be stacked together without a perfect lattice match but only a small difference exists between the lattice constants of the two semiconductors and the lattice mismatch produces no significant defects. The difference between the lattice constants is absorbed by elastic deformation of the crystal lattices of the respective semiconductors. For example, a pseudo lattice match is established between Ge and GaAs when the two different semiconductors are stacked together.

The semiconductor device 480 is, for example, a MOSFET the active region 440 of which is formed using a portion of the compound semiconductor 466. The regions 432 and 434 are respectively to constitute the source region and the drain region of the semiconductor device 480.

When the compound semiconductor 466 is grown by MOCVD, the pressure may be set at no lower than 0.1 kPa and no higher than 100 kPa. A high pressure is not preferable since crystals are likely to be grown on the inhibition layer. The pressure is preferably set at no higher than 50 kPa. The growth rate of the compound semiconductor 466 is dependent on the area ratio of the opening 428 formed in the inhibition layer 426. The area ratio is defined as the result of dividing the bottom area of the opening by the area of a portion of the wafer, the portion being in contact with the inhibition layer. As the area ratio of the opening 428 decreases, the growth rate increases since more precursors gather at the opening.

The regions 432 and 434 are formed, for example, in the following manner. To begin with, the gate insulator 454 is formed in contact with the compound semiconductor 466. The examples of the gate insulator 454 can include an AlGaAs film, an AlInGaP film, a silicon oxide film, a silicon nitride film, an aluminum oxide film, a gallium oxide film, a gadolinium oxide film, a hafnium oxide film, a zirconium oxide film, a lanthanum oxide film, and a mixture or a multi-layer film of these films. For example, the gate insulator 454 can be formed by, after forming a thin film by MOCVD, MBE or ALD, patterning the thin film.

Subsequently, the gate electrode 452 is formed in contact with the gate insulator 454. The gate electrode 452 may be made of a metal such as Ag, Au, Al, Pt, or Pd, or structured such that a metal such as Ag, Au, Al, Pt, or Pd is layered on a conductive material such us TaC, TaN, or TiN. For example, the gate electrode 452 can be formed by, after forming a thin film by sputtering or vacuum evaporation, patterning the thin film by etching or the like.

After this, a resist, not shown, is formed on the compound semiconductor 466. The resist is shaped in accordance with the shapes of the regions 432 and 434. Subsequently, for example, ion implantation is performed by using the gate electrode 452 and the gate insulator 454 as a musk in order to implant impurities into the compound semiconductor 466. The resist is then removed. In this way, the regions 432 and 434 are obtained.

Following this, the electromagnetic wave 10 is applied to the base wafer 420 from above the base wafer 420. The electromagnetic wave 10 is, for example, a flash produced by a flash lamp. The electromagnetic wave 10 has a wavelength that is likely to be absorbed by the regions 432 and 434 and reflected by the gate electrode 452.

In this way, the gate electrode 452 reflects at least a portion of the electromagnetic wave 10. Here, the gate insulator 454 restrains the heat generated in the gate electrode 452 as a result of the application of the electromagnetic wave 10 from reaching the active region 440. In this manner, the boundary with low thermal resistance between the active region 440 and the gate insulator 454 is protected from the heat generated by the application of the electromagnetic wave 10.

On the other hand, the temperatures of the regions 432 and 434 rise as the regions 432 and 434 absorb the electromagnetic wave 10. This recovers the crystallinity of the regions 432 and 434 and activates the impurities introduced by ion implantation. As described above, while the temperature of the active region 440 or the temperature of the boundary between the active region 440 and the gate insulator 454 is prevented from rising, the regions 432 and 434 are selectively heated to form the source region and the drain region of the semiconductor device 480. Here, the method to form the impurity region such as the source region and the drain region is not limited to the above-described method. The impurity region may be alternatively formed by diffusing impurities.

The semiconductor device 480 may be formed in a compound semiconductor that is gown along the opening 428 with the compound semiconductor 466 serving as a nucleus. The protective layer 450 is not limited to the gate electrode 452 and the gate insulator 454 of the semiconductor device 480. The protective layer 450 may be formed on the gate side wall of the gate electrode 452. This can restrain the thermal diffusion and the impurity diffusion from adversely affecting the gate portion.

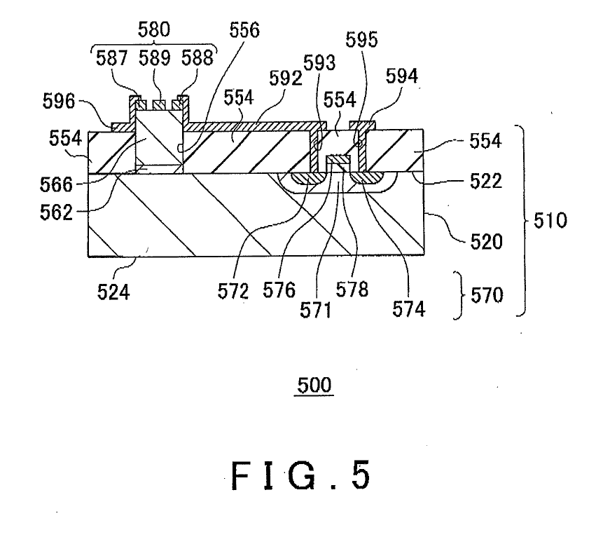

FIG. 5 schematically illustrates an exemplary cross-section of an electronic device 500. The electronic device 500 includes a second electronic element 580, an interconnection 592, an interconnection 594, and an interconnection 596 that are formed on a semiconductor wafer 510.

The semiconductor wafer 510 includes a base wafer 520, a first electronic element 570, an inhibition layer 554, a SiₓGe₁₋ₓ crystal 562, and a group III-V compound semiconductor 566. The base wafer 520 has a first main plane 522 and a second main plane 524. The base wafer 420 is, for example, any one of a Si wafer, an SOI wafer, a Ge wafer, a GOI wafer, and a GaAs wafer.

On the base wafer 520, the first electronic element 570 is formed. The first electronic element 570 includes a well 571, a source region 572, a drain region 574, a gate electrode 576, and a gate insulator 578. The first electronic element 570 may have the same configuration as the semiconductor device 480 described with reference to FIG. 4. The first electronic element 570 is equivalent to the portion to be protected 140 described with reference to FIGS. 1 to 3.

The inhibition layer 554 is formed on the base wafer 520 and the first electronic element 570, using the same material and the same method as the inhibition layer 426 described with reference to FIG. 4. In the inhibition layer 554, an opening 556, an opening 593, and an opening 595 are formed. The second electronic element 580 includes an input/output electrode 587, an input/output electrode 588, and a gate electrode 589. The second electronic element 580 is formed on the group III-V compound semiconductor 566.

The inhibition layer 554 and the opening 556 arc respectively equivalent to the inhibition layer 426 and the opening 428. Therefore, the following description of the inhibition layer 554 and the opening 556 only focuses on their difference from the inhibition layer 426 and the opening 428. The inhibition layer 554 is different from the inhibition layer 426 in terms of having the opening 593 and the opening 595. The inhibition layer 554 serves as a protective layer that protects the first electronic element 570, which is shown as an exemplary portion to be protected, from an electromagnetic wave. The inhibition layer 554 may serve as the above-described thermal conduction restraining layer.

The openings 593 and 595 penetrate through the inhibition layer 554 in the substantially perpendicular direction to the first main plane 522. The opening 593 and the opening 595 externally expose the source region 572 and the drain region 574 respectively. Within the opening 593 and the opening 595, a portion of the interconnection 592 and a portion of the interconnection 594 are respectively formed. In this way, the first electronic element 570 is electrically coupled to another electronic element such as the second electronic element 580. The openings 593 and 595 can be formed, for example, by reactive ion etching.

The SiₓGe₁₋ₓ crystal 562 is an exemplary seed crystal that provides a good seed plane for growing the group III-V compound semiconductor 566. Here, x represents a real number satisfying the condition of 0≦x<1. The SiₓGe₁₋ₓ crystal 562 prevents the impurities present in the base wafer 520 or the first main plane 522 from adversely affecting the crystallinity of the group III-V compound semiconductor 566. The SiₓGe₁₋ₓ crystal 562 is formed within the opening 556. The SiₓGe₁₋ₓ crystal 562 may be in contact with the first main plane 522. The SiₓGe₁₋ₓ crystal 562 may be formed in the same manner and under the same condition as the seed crystal 462 described with reference to FIG. 4.

After the inhibition layer 554 is formed that protects the first electronic element 570 from an electromagnetic wave, the electromagnetic wave 10 that is capable of being absorbed by the SiₓGe₁₋ₓ crystal 562 is applied to the semiconductor wafer 510. In this manner, the SiₓGe₁₋ₓ crystal 562, which is a portion to be thermally processed, is selectively heated. The protective layer may represent at least a partial region of a portion of the inhibition layer 554 included in the semiconductor wafer 510, the portion being other than the openings.

The group III-V compound semiconductor 566 has a lattice match or a pseudo lattice match with the SiₓGe₁₋ₓ crystal 562. The group III-V compound semiconductor 566 is, for example, GaAs. The group III-V compound semiconductor 566 is formed, by crystal growth, so as to be in contact with the SiₓGe₁₋ₓ crystal 562, for example.

To form, by crystal growth, the group III-V compound semiconductor 566, an electromagnetic wave is applied to the base wafer 520 in order to raise the temperature of the group III-V compound semiconductor 566 to a temperature necessary for the crystal growth. The crystal growth of the group III-V compound semiconductor 566 may be performed using the light source used to anneal the SiₓGe₁₋ₓ crystal 562 and involve applying the same electromagnetic wave again.

The boundary between the SiₓGe₁₋ₓ crystal 562 and the group III-V compound semiconductor 566 may be positioned within the opening 556. The group III-V compound semiconductor 566 is formed, for example, by epitaxial growth such as MOCVD. When the base wafer 520 is a Ge wafer or a GOI wafer, in other words, a wafer the first main plane 522 of which includes a SiₓGe₁₋ₓ crystal (0≦x<1), the group III-V compound semiconductor 566 may be formed in contact with the first main plane 522.

When the group III-V compound semiconductor 566 is epitaxially grown by MOCVD, the source gas may be supplied to the reaction chamber while the electromagnetic wave that is capable of being absorbed by the SiₓGe₁₋ₓ crystal 562 is applied to the base wafer 520 with the inhibition layer 554 that protects the first electronic element 570 from an electromagnetic wave being formed on the base wafer 520. In this manner, a group III-V compound semiconductor that has a lattice match or a pseudo lattice match with the annealed SiₓGe₁₋ₓ crystal 562 can be selectively grown.

In this case, the temperature of the base wafer 520, in particular, the temperature of the region in which the first electronic element 570 is formed is maintained at, for example, 650° C. or lower, preferably 450° C. or lower. Therefore, the heat-induced degradation of the first electronic element 570 can be restrained. Note that the temperature of the base wafer 520 is maintained at 650° C. or lower, preferably 450° C. or lower in either of the case where the SiₓGe₁₋ₓ crystal 562 is formed on the base wafer 520 and the case where the SiₓGe₁₋ₓ crystal 562 is annealed.

The first electronic element 570 is formed in a region of the base wafer 520, the region being other than the region that is externally exposed through the opening 556. The first electronic element 570 may be an active element included in a semiconductor device such as a MISFET, a HET and a HEMT, a light emitting device such as a LED, a light receiving device such as an optical sensor, or a passive element included in a capacitor or the like. The first electronic element 570 may be an electronic element included in any circuit among the driving circuit for the second electronic element 580, the correction circuit for improving the linearity of the input and output characteristics of the second electronic element 580, and the protection circuit for the input stage of the second electronic element 580.

The second electronic element 580 may be an electronic element included in any device among an analog electronic device, a light emitting device such as an LED, and a light receiving device such as an optical sensor. Alternatively, the second electronic element 580 may be a passive element included in a semiconductor device such as a MOSFET, a MISFET, a HBT, and a HEMT, or a capacitor.

The input/output electrode 587, the input/output electrode 588, and the gate electrode 589 may be made of an electrically conductive material. For example, the input/output electrode 587, the input/output electrode 588, and the gate electrode 589 can be made of a metal such as Al, W or Ti, or a highly impurity-doped semiconductor. The input/output electrode 587, the input/output electrode 588, and the gate electrode 589 can be formed, for example, by vacuum evaporation or plating.

The interconnections 592, 594, and 596 electrically couple the first electronic element 570 or the second electronic element 580 to another electronic element or the like. The interconnections 592, 594, and 596 are made of an electrically conductive material. For example, the interconnections 592, 594, and 596 can be made of a metal such as Al, Cu, Au, W or Ti, or an impurity-doped semiconductor. The interconnections 592, 594, and 596 can be formed, for example, by vacuum evaporation or plating.

The semiconductor wafer 510 may include a plurality of first electronic elements 570. Each first electronic element 570 may be electrically coupled to a plurality of second electronic elements 580. The semiconductor wafer 510 may include a plurality of second electronic elements 580. Each second electronic element 580 may be electrically coupled to a plurality of first electronic elements 570.

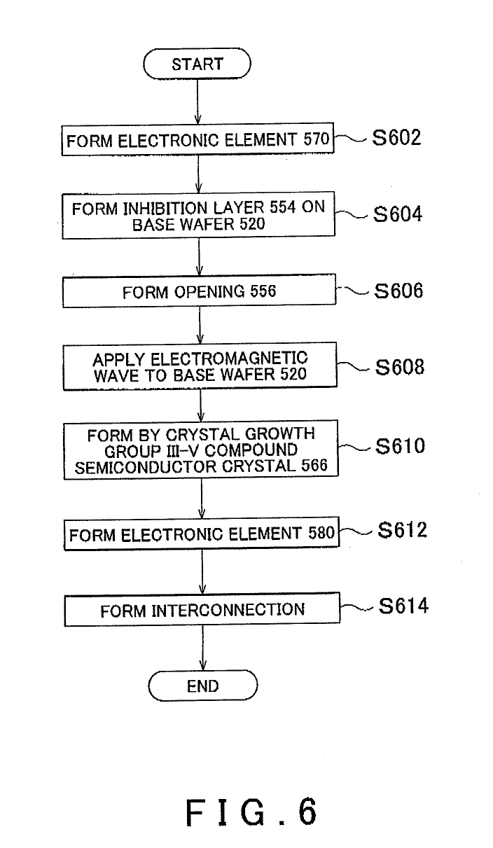

FIG. 6 is a flow chart to illustrate an exemplary method of producing the electronic device 500. In a step S602, the first electronic element 570 is formed on the base wafer 520. Subsequently, in a step S604, the inhibition layer 554 is formed to cover at least the first electronic element 570. The inhibition layer 554 serves to inhibit crystal growth of the SiₓGe₁₋ₓ crystal 562 and to protect the first electronic element 570 from the electromagnetic wave 10. Subsequently, in a step 5606, the opening 556 is formed in a region of the inhibition layer 554, the region being other than the region that covers the first electronic element 570. The opening 556 penetrates through the inhibition layer 554 to reach the base wafer 520.

Subsequently, in a step S608, the SiₓGe₁₋ₓ crystal 562 is formed as a portion to be thermally processed, within the opening 556. In other words, the precursors of the SiₓGe₁₋ₓ crystal 562 are grown into a crystal within the opening 556. Furthermore, in a step S610, the SiₓGe₁₋ₓ crystal 562 is annealed by applying the electromagnetic wave 10 to the base wafer 520 while the entire base wafer 520 is heated.

After this, in a step S612, the group III-V compound semiconductor 566 is formed, by crystal growth, on the SiₓGe₁₋ₓ crystal 562. In a step S614, the second electronic element 580 is formed on the group III-V compound semiconductor 566. Finally in a step S616, the openings 593 and 595 are formed in the inhibition layer 554. Furthermore, the interconnections 592, 594, and 596 are formed. Thus, the electronic device 500 is produced.

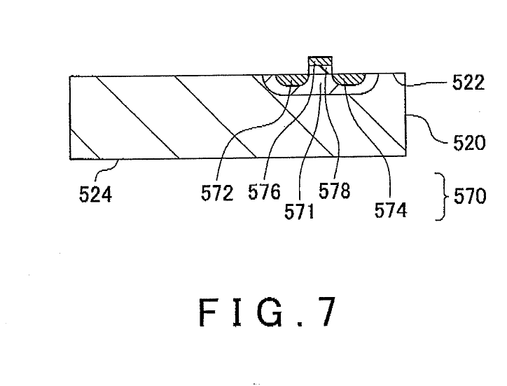

The following describes an exemplary method for producing the semiconductor wafer 510 with reference to FIGS. 7 to 11. FIG. 7 schematically illustrates an exemplary cross-section observed during the production process of the semiconductor wafer 510. In the present embodiment, the first electronic element 570 is first formed on the base wafer 520. The base wafer 520 is, for example, a Si wafer or an SOI wafer.

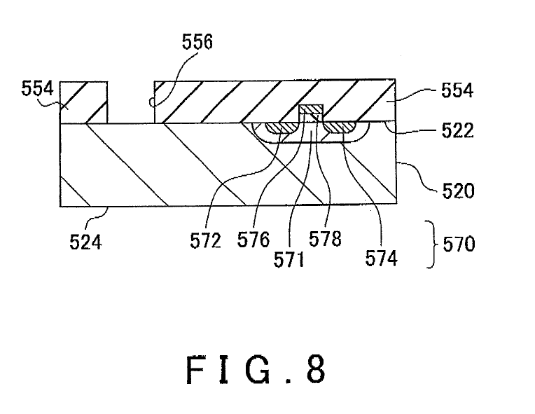

FIG. 8 schematically illustrates an exemplary cross-section observed during the production process of the semiconductor wafer 510. As shown in FIG. 8, the inhibition layer 554 is formed in contact with the first main plane 522 of the base wafer 520. The inhibition layer 554 is, for example, made of SiO₂. The inhibition layer 554 has the thickness of, for example, 0.05 μm to 5 μm. The inhibition layer 554 may be formed by CVD. In the inhibition layer 554, for example, the opening 556 is formed by photolithography such as etching. The opening 556 may have an aspect ratio of (√3)/3 or higher.

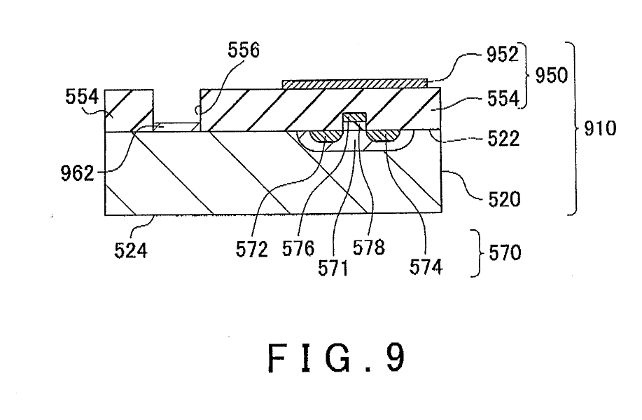

FIG. 9 schematically illustrates an exemplary semiconductor wafer 910 observed during the production process of the semiconductor wafer 510. As shown in FIG. 9, a SiₓGe₁₋ₓ crystal 962 is formed in the opening 556 by epitaxial growth. The SiₓGe₁₋ₓ crystal 962 corresponds to the portion to be thermally processed 130 described with reference to FIGS. 1 to 3.

The SiₓGe₁₋ₓ crystal 962 can be formed, for example, by CVD using a source gas containing halogen. Since the precursors of the SiₓGe₁₋ₓ crystal 962 are inhibited from growing into a crystal on the front plane of the inhibition layer 554, the SiₓGe₁₋ₓ crystal 962 is selectively grown within the opening 556. Here, defects such as lattice defects may occur within the SiₓGe₁₋ₓ crystal 962.

Annealing the SiₓGe₁₋ₓ crystal 962 can reduce the density of the defects within the SiₓGe₁₋ₓ crystal 562. However, since a portion of the first electronic element 570 has already been formed on the base wafer 520, applying an electromagnetic wave to the base wafer 520 to perform high-temperature annealing at the temperature of 800° C. to 900° C. may damage the first electronic element 570. In addition, the impurities included in the well 571, the source region 572, and the drain region 574 are further diffused. To remove such drawbacks, a protective layer 950 is provided to protect the first electronic element 570 from an electromagnetic wave. As a result, the SiₓGe₁₋ₓ crystal 962 can be selectively heated.

As shown in FIG. 9, a block layer 952 may be formed on the front plane of the inhibition layer 554 in a region covering the first electronic element 570. The inhibition layer 554 and the block layer 952 serve as the protective layer 950. The block layer 952 may have the same function and the same configuration as the block layer 252 described with reference to FIG. 2. The block layer 952 is, for example, a metal thin film that reflects at least a part of an electromagnetic wave. The metal thin film can be formed, for example, by vacuum evaporation. The block layer 952 is formed to have a size large enough to protect the first electronic element 570 from an electromagnetic wave. The block layer 952, the inhibition layer 554, and the first electronic element 570 may be arranged in the stated order in the direction in which an electromagnetic wave transmits.

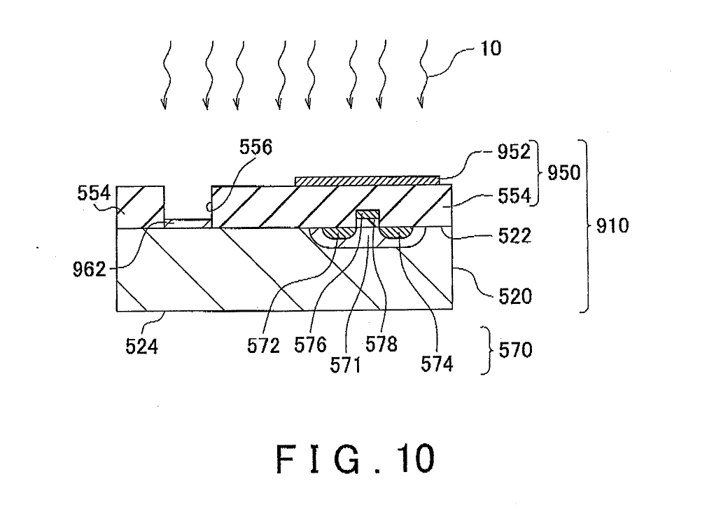

FIG. 10 schematically illustrates the exemplary semiconductor wafer 910 observed during the production process of the semiconductor wafer 510. As shown in FIG. 10, the electromagnetic wave 10 is applied to the base wafer 520 from above. The electromagnetic wave 10 is, for example, a flash produced by a flash lamp.

The wavelength of the electromagnetic wave 10 is preferably selected such that the electromagnetic wave 10 is likely to be absorbed by the Si_{X}Ge₁₋ₓ crystal 962 and blocked by the block layer 952. For example, when the block layer 952 is a metal thin film, the wavelength of the electromagnetic wave 10 is selected such that the electromagnetic wave 10 is likely to be reflected by the block layer 952. Alternatively, the wavelength of the electromagnetic wave may be selected such that the electromagnetic wave is unlikely to be absorbed by the inhibition layer 554. In this way, the SiₓGe₁₋ₓ crystal 962 is selectively heated. Accordingly, the SiₓGe₁₋ₓ crystal 962 is annealed. This annealing can be performed under the same conditions as the annealing for the portion to be thermally processed 130. Here, since the first electronic element 570 is protected from the electromagnetic wave 10, the temperature of the first electronic element 570 is prevented from rising.

Prior to the step of selectively heating the SiₓGe₁₋ₓ crystal 962, the semiconductor wafer 910 may be preheated. The preheating can be performed, for example, in such a manner that a support that has been heated to a prescribed temperature is brought into contact with the second main plane 524 of the base wafer 520 to heat the entire semiconductor wafer 910 by means of thermal conduction from the support to the semiconductor wafer 910. In this way, at least the SiₓGe₁₋ₓ crystal 962 and the first electronic element 570 are heated.

The preheating can also be performed by applying, to the base wafer 520, an electromagnetic wave that is capable of being absorbed by the base wafer 520 from the side of the second main plane 524 of the base wafer 520 and thus heating the entire semiconductor wafer 910. The preheating is performed to such an extent that the temperature of the first electronic element 570 does not exceed the temperature at which the first electronic element 570 may be thermally deteriorated.

The annealing reduces the density of the defects in the SiₓGe₁₋ₓ crystal 962, so that the SiₓGe₁₋ₓ crystal 562 accomplishes superior crystallinity. For example, the average dislocation density is lowered to 10⁵ cm⁻² or lower for the threading dislocations that reach the front plane of the SiₓGe₁₋ₓ crystal 562. The average dislocation density can be measured by the etch-pit method or plan-view cross-sectional observation based on a transmission electron microscope.

The step of growing the precursors of the SiₓGe₁₋ₓ crystal 962 into a crystal, the step being described in connection with FIG. 9, and the step of selectively heating the SiₓGe₁₋ₓ crystal 962, the step being described in connection with FIG. 10 are, for example, performed in the same reaction chamber. Furthermore, the step of growing the precursors of the SiₓGe₁₋ₓ crystal 962 into a crystal may be successively followed by the step of selectively heating the SiₓGe₁₋ₓ crystal 962, without exposing the SiₓGe₁₋ₓ crystal 962 to air between the steps.

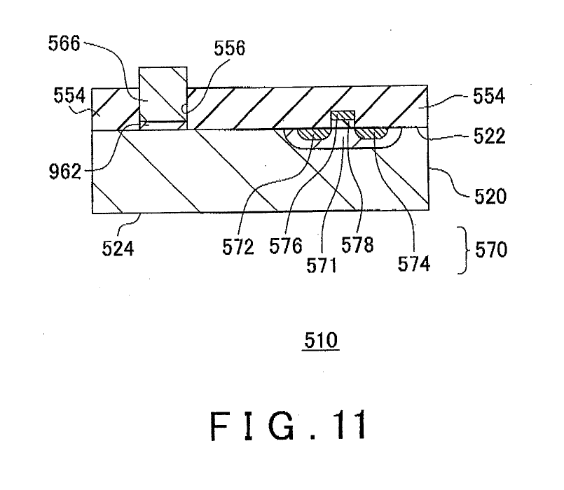

FIG. 11 schematically illustrates an exemplary cross-section of the semiconductor wafer 510. The group III-V compound semiconductor 566 is formed on the SiₓGe₁₋ₓ crystal 962. The group III-V compound semiconductor 566 has a lattice match or a pseudo lattice match with the SiₓGe₁₋ₓ crystal 962. For example, the group III-V compound semiconductor 566 is epitaxially grown by using as a seed plane the front plane of the SiₓGe₁₋ₓ crystal 962 having superior crystallinity (the reference numeral 962 is also used in the drawings). The group III-V compound semiconductor 566 can be formed by, for example, MOCVD.

The group III-V compound semiconductor 566 is preferably formed by crystal growth with the protective layer 950 being formed in the semiconductor wafer 910. In this way, the group III-V compound semiconductor 566 can be obtained that has a lattice match or a pseudo lattice match with the SiₓGe₁₋ₓ crystal 562 while the temperature of the first electronic element 570 is prevented from rising. For example, the source gas is supplied to the reaction chamber while the electromagnetic wave that is capable of being absorbed by the SiₓGe₁₋ₓ crystal 962 is applied to the wafer with the inhibition layer 554 that covers the first electronic element 570 being formed and with the block layer 952 that protects the first electronic element 570 from an electromagnetic wave being formed. In this manner, the group III-V compound semiconductor that has a lattice match or a pseudo lattice match with the SiₓGe₁₋ₓ crystal 962 can be selectively grown on the front plane of the annealed SiₓGe₁₋ₓ crystal 962.

During the growth, the temperature of the base wafer 520, in particular, the temperature of the region in which the first electronic element 570 is formed is maintained at, for example, 650° C. or lower, preferably 450° C. or lower. This can further reduce the heat-induced deterioration of the first electronic element 570. The temperature of the base wafer 520 is also maintained at 650° C. or lower, preferably 450° C. or lower while the SiₓGe₁₋ₓ crystal 962 is formed on the base wafer 520, while the semiconductor wafer 910 is preheated, and the SiₓGe₁₋ₓ crystal 962 is annealed.

After the group III-V compound semiconductor 566 is formed, the block layer 952 is removed by etching or the like. Thus, the semiconductor wafer 510 is produced. Following this, the second electronic element 580, the interconnections 592, 594 and 596, and the like are formed so that the first electronic element 570 is electrically coupled to the second electronic element 580. As a result, the electronic device 500 is produced.

In the present embodiment, the case where the block layer 952 is removed has been explained. Alternatively, however, a portion of the block layer 952 may be left to be used as a portion of the interconnection 592 or 594. In the present embodiment, the case where the group III-V compound semiconductor 566 is formed by crystal growth with the block layer 952 being formed has been explained. Alternatively, however, the group III-V compound semiconductor 566 may be formed by crystal growth after the block layer 952 has been removed.

In the present embodiment, the case where the block layer 952, the inhibition layer 554, and the first electronic element 570 are arranged in the stated order in the transmission direction of the electromagnetic wave has been explained. Alternatively, however, the inhibition layer 554, the block layer 952, and the first electronic element 570 may be arranged in the stated order in the transmission direction of the electromagnetic wave. In other words, an inhibition layer, a protective layer, and a portion to be protected may be arranged in the stated order in the transmission direction of an electromagnetic wave. By employing the alternative arrangement, the SiₓGe₁₋ₓ crystal 962 can be selectively heated after the protective layer is formed.

In the present embodiment, the case where the SiₓGe₁₋ₓ crystal 962 is selectively heated by providing the protective layer 950 in the semiconductor wafer 910 to protect the first electronic element 570 from an electromagnetic wave has been explained. However, the SiₓGe₁₋ₓ crystal 962 may be selectively heated in different manners.

Specifically speaking, the semiconductor wafer 910 may have a heat generating layer that absorbs an electromagnetic wave to generate heat, in the vicinity of the SiₓGe₁₋ₓ crystal 962. In this way, applying an electromagnetic wave to the semiconductor wafer 910 selectively causes the heat generating layer to generate heat. As a result, the heat generated by the heat generating layer can selectively heat the SiₓGe₁₋ₓ crystal 962 without raising the temperature of the entire semiconductor wafer 910. The heat generating layer includes, for example, amorphous silicon. The above-described heating method may be employed when the group III-V compound semiconductor 566 is epitaxially grown on the front plane of the SiₓGe₁₋ₓ crystal 962.

According to another exemplary method of selectively heating the SiₓGe₁₋ₓ crystal 962, an electromagnetic wave that is likely to be absorbed by the SiₓGe₁₋ₓ crystal 962 but unlikely to be absorbed by the base wafer 520 and the first electronic element 570 may be applied to the base wafer 520. In this way, the SiₓGe₁₋ₓ crystal 962 can be selectively heated. This method may be employed when the group III-V compound semiconductor 566 is epitaxially grown on the front plane of the SiₓGe₁₋ₓ crystal 962.

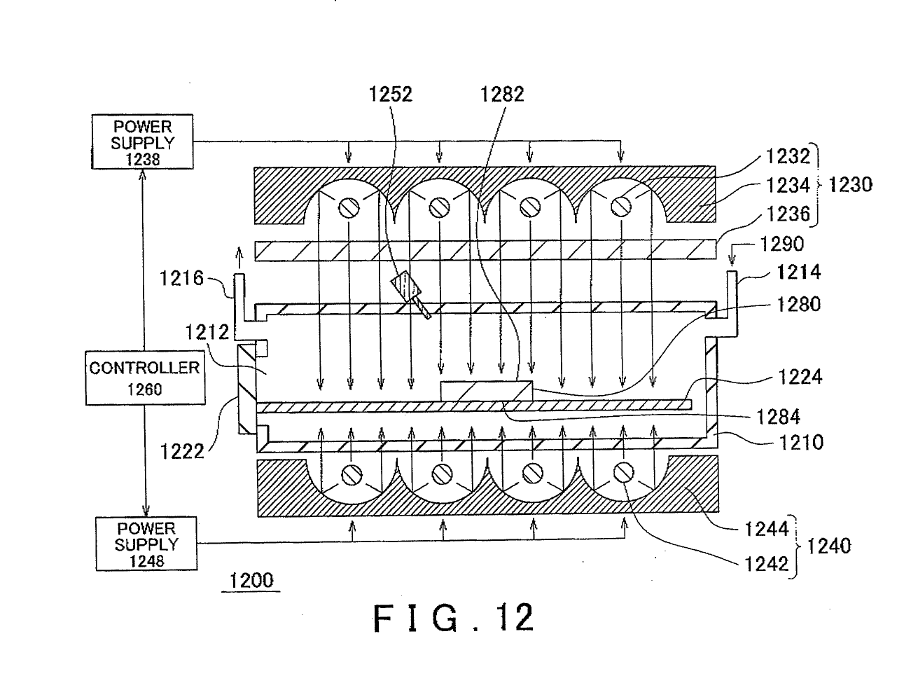

FIG. 12 schematically illustrates an exemplary cross-section of a thermal process apparatus 1200. The thermal process apparatus 1200 houses a base wafer 1280 therein. The base wafer 1280 has the same configuration as, for example, any of the base wafer 120, the base wafer 420, and the base wafer 520. On a first main plane 1282 of the base wafer 1280, as an example, the portion to be thermally processed 130 that has a single-crystal layer and is to be thermally processed, the portion to be protected 140 that is to be protected from the heat to be added during the thermal processing, and the protective layer 150 that protects the portion to be protected from an electromagnetic wave.

The thermal process apparatus 1200 is shown as an exemplary reaction apparatus. For example, the thermal process apparatus 1200 performs a thermal processing such as flash annealing on the base wafer 1280. The thermal process apparatus 1200 may also serve as a CV D apparatus that forms a Si crystal, a SiₓGe₁₋ₓ crystal (0≦x<1), a compound semiconductor crystal and the like on the base wafer 1280.

The thermal process apparatus 1200 includes a thermal process furnace 1210, a lamp unit 1230, a lamp unit 1240, a radiation thermometer 1252, and a controller 1260. The thermal process furnace 1210 has a wafer loading opening 1212, a gas inlet 1214, a gas outlet 1216, and a flap 1222. The lamp unit 1230 has lamps 1232, a reflector 1234, a filter 1236, and a power supply 1238. The lamp unit 1240 has lamps 1242, a reflector 1244, and a power supply 1248.

The thermal process furnace 1210 houses the base wafer 1280 therein. The thermal process furnace 1210 is shown as an exemplary reaction chamber. The thermal process furnace 1210 is, for example, hollow and has a cylindrical shape. The wafer loading opening 1212 is used to load or unload the base wafer 1280. The flap 1222 tightly closes the wafer loading opening 1212. The flap 1222 may include a support 1224 that supports the base wafer 1280 within the thermal process apparatus 1200. In this way, the base wafer 1280 can be retained within the thermal process furnace 1210.

The support 1224 is, for example, a graphite susceptor. On the support 1224, a temperature sensor may be disposed as a heating temperature measuring section that measures the temperature of the support 1224. The base wafer 1280 may be placed on the support 1224 in contact with the support 1224. In this case, the temperature of the lower portion of the base wafer 1280 is substantially the same as the temperature of the support 1224. Accordingly, the above-mentioned temperature sensor can measure the temperature of the back plane of the base wafer 1280. For example, the temperature sensor can measure the temperature of a low-heat-resistance portion formed in the base wafer 1280. The temperature sensor may measure the temperature of a region of the base wafer 1280, the region being in the vicinity of the Si device or the group III-V compound semiconductor device formed in the base wafer 1280.

An inert gas or the like is supplied into the thermal process furnace 1210 through the gas inlet 1214. Furthermore, the gas present within the thermal process furnace 1210 may be discharged through the gas outlet 1216. The gas inlet 1214 supplies, into the thermal process furnace 1210, a source gas used by CVD, MOCVD and the like. For example, the gas inlet 1214 supplies, into the thermal process furnace 1210, a source gas 1290, a carrier gas, and the like. The carrier gas is, for example, a hydrogen gas.

The source gas 1290 experiences a reaction within the thermal process furnace 1210, as a result of which a semiconductor crystal is epitaxially grown on the base wafer 1280 retained within the thermal process furnace 1210. The residual gas and the like present within the reaction chamber is discharged through the gas outlet 1216. Although not shown, the gas outlet 1216 may be connected to a vacuum system.

The temperature of the source gas 1290 is lower than the temperature of the base water 1280. It is preferable that the source gas 1290 is used to cool the base wafer 1280 while an electromagnetic wave is applied to the base wafer 1280 to epitaxially grow a semiconductor crystal. By cooling the base wafer 1280 while applying an electromagnetic wave to the baser wafer 1280, the portion to be thermally processed 130 can be selectively heated with it being possible to maintain the difference in temperature between the portion to be thermally processed 130 and the remaining region of the base wafer 1280.

The lamp unit 1230 is shown as an exemplary irradiating section. The lamp unit 1230 is positioned so as to face the first main plane 1282 of the base wafer 1280. The lamp unit 1230 applies an electromagnetic wave to the base wafer 1280 from the side of the first main plane 1282 of the base wafer 1280. In this manner, the lamp unit 1230 heats the base wafer 1280.

Each lamp 1232 generates an electromagnetic wave. Each lamp 1232 generates, for example, light including infrared light. Each lamp 1232 may generate incoherent light to uniformly apply an electromagnetic wave to the entire base wafer 1280. For example, the thermal process apparatus 1200 is configured such that a large number of low-cost light sources are arranged in parallel in order to uniformly apply an electromagnetic wave to the entire base wafer 120. Consequently, the thermal process apparatus 1200 can thermally process the base wafer 120 having a large area by a single operation. The lamps 1232 are each, for example, a high-intensity discharge lamp, a halogen lamp, a xenon lamp, or an LED lamp. The high-intensity discharge lamp is, for example, a high-pressure mercury lamp, a metal halide lamp, or a sodium lamp.

The lamp unit 1230 may continuously apply an electromagnetic wave, or apply an electromagnetic wave that has been pulsed, multiple times. The lamp unit 1230 may determine the duration of each pulse of an electromagnetic wave and the number of the pulses of the electromagnetic wave according to the purpose of the application of the electromagnetic wave.

For example, the lamp unit 1230 performs flash annealing by applying, to the base wafer 1280, an electromagnetic wave that has been pulsed, multiple times. To perform flash annealing, the lamp unit 1230 applies flashes to the base wafer 1280 using flash lamps such as xenon lamps. The superficial portion of the base wafer 1280 is heated to a high temperature of for example, 1000° C. or higher within a short period of time. Furthermore, the base wafer 1280 is scanned while the flashes produced by the flash lamps are applied to the base wafer 1280. Consequently, the entire plane of the base wafer 1280 is heated.

The pulse width of the electromagnetic wave applied by the flash lamps is, for example, 1 ns to 100 ms. When the base wafer 1280 is thermally processed at a high temperature, the pulse width of the electromagnetic wave preferably is short. However, the pulse width of shorter than 0.1 ms makes it difficult to control the light pulse. Therefore, the pulse width of the electromagnetic wave is preferably 0.1 ms to 10 ms. As used herein, the term “pulse width” represents the duration for which the level of the pulse waveform remains at or above half the peak value.

The dose of the flash can be arbitrarily selected depending on what is to be thermally processed and what lamps are available. The dose is, for example, set to 2 to 50 J/cm². As used herein, a dose of a flash lamp is defined as a result of dividing the energy (unit: J) of the electromagnetic wave output from the flash lamp by the area (unit: cm²) of a region of the base wafer 1280, the region being exposed to the flash output from the flash lamp.

When a flash is applied in multiple pulses, the interval between the pulses of the flash is determined considering the output performance of the flash source and the repetitive charge/discharge performances of the flash source, and the heat releasing characteristics of the portion to be thermally processed 130. For example, the interval between the pulses is determined such that the temperature of the portion to be thermally processed 130 reaches a temperature necessary for annealing while the temperature of the portion to be protected 140 does not reach prescribed temperature or higher. The interval between the pulses is, for example, 1 s or longer.

When the interval between the pulses is too short, the requirement for the charge/discharge equipment becomes excessively high. In addition, the temperature of the portion to be protected 140 may unnecessarily rise since the thermal energy is not sufficiently released from the base wafer 1280. On the other hand, when the interval between the pulses is too long, a long period of time is required to complete a thermal processing and an increased energy is required for the thermal processing.

The number of pulses produced by the flash lamps and the width of each pulse may be freely set so that the portion to be thermally processed 130 is annealed to a sufficient extent. By adjusting the number of pulses produced by the flash lamps or the width of each pulse, the temperature and duration or the thermal processing can be adjusted.

For example, when the portion to be thermally processed 130 includes a SiₓGe₁₋ₓ crystal (0≦x<1) and the portion to be thermally processed 130 is annealed by continuous annealing using continuous light, the temperature of the thermal processing is set at 850° C. to 900° C. and the duration of the thermal processing is set at 2 to 10 minutes. The temperature for the annealing is, for example, set lower than the melting point of the portion to be thermally processed 130.

To perform flash annealing, for example, a lamp having a dose of 5 J/cm² is used to apply a flash having a wide emission spectrum with a wavelength range of 0.2 μm to 1.5 μm in approximately five pulses with the width of the pulse being set at 1 ms and the interval between the pulses being set at 30 s. This accumulates to application for a duration of approximately 5 ms and can bring the maximum reachable temperature of the portion to be thermally processed 130 to a temperature of 750° C. and 800° C.

Alternatively, the base wafer 1280 may be preheated in advance to a temperature of approximately 400° C. and 600° C., a lamp having a dose of 5 J/cm² may be similarly used to apply a flash having a similar wavelength range in approximately five pulses with the width of the pulse being set at 5 ms and the interval between the pulses being set at 30 s. This can bring the maximum reachable temperature of the portion to be thermally processed 130 to a temperature of 850° C. to 900° C.

The base wafer 1280 may be subjected to multi-stage annealing. For example, the base wafer 1280 may be first subjected to high-temperature annealing at a temperature that is lower than the melting point of the portion to be thermally processed 130, and then subjected to low-temperature annealing at a temperature lower than the temperature of the high-temperature annealing. In addition, the above-mentioned two-stage annealing may be repeatedly performed multiple times. For example, the temperature of the high-temperature annealing is set at 850° C. to 900° C. and the duration of the high-temperature annealing is set at 2 to 10 minutes when the portion to be thermally processed 130 includes a SiₓGe₁₋ₓ crystal (0≦x<1). On the other hand, the temperature of the low-temperature annealing is set at 600° C. to 780° C. and the duration of the low-temperature annealing is set at 2 to 10 minutes, for example. The above-described two-stage annealing is, for example, performed ten times.

When the portion to be thermally processed 130 is annealed by flash annealing, the above-described multi-stage annealing can be realized by adjusting the conditions of the flash annealing, such as the pulse width and the pulse duration. For example, when the two-stage annealing is realized in accordance with the flash-annealing scheme, the conditions such as the pulse width are adjusted such that the first flash causes the maximum reachable temperature of the portion to be thermally processed 130 to fall within the temperature range of the high-temperature annealing. Here, the temperature of the portion to be thermally processed 130 falls between the first flash and the next flash. Therefore, the pulse interval may be adjusted such that the next flash causes the temperature of the portion to be thermally processed 130 to fall within the temperature range of the low-temperature annealing.

The reflector 1234 reflects, among the electromagnetic waves applied from the lamps 1232, the electromagnetic waves that do not travel towards the base wafer 1280, toward the base wafer 1280. The power supply 1238 adjusts the currents supplied to the lamps 1232, for example, based on the signal received from the controller 1260.

The filter 1236 is positioned between the base wafer 1280 and the lamps 1232. The filter 1236 may at least partially block the wavelengths of an electromagnetic wave, the wavelengths being capable of being absorbed by the base wafer 1280. The filter 1236 absorbs specific wavelengths, among the wavelengths of the electromagnetic wave generated by the lamps 1232. For example, among the wavelengths of the electromagnetic wave applied from the lamps 1232, the filter 1236 blocks the wavelengths at which the portion to be protected 140 of the base wafer 1280 has a higher absorption coefficient than the portion to be thermally processed 130 of the base wafer 1280.

The filter 1236 may include the same material as the portion to be protected 140 when the base wafer 1280 has the portion to be protected 140. For example, when the portion to be protected 140 is a MOSFET formed in a Si crystal of a Si wafer, an SOI wafer or the like, a filter including a Si crystal, for example, a Si crystal wafer, is used. In this way, the base wafer 1280 can be exposed to an electromagnetic wave that is not absorbed by the Si crystal but can selectively heat a SiₓGe₁₋ₓ crystal (0≦x<1). As an alternative example, a Si crystal wafer having an SiO₂ layer formed thereon may be used as the filter. In this case, the base wafer 1280 can be exposed to an electromagnetic wave that is absorbed neither by the Si crystal nor by SiO₂ and can selectively heat a SiₓGe₁₋ₓ crystal (0≦x<1).

When the thermal process apparatus 1200 anneals the portion to be thermally processed 130 including a SiₓGe₁₋ₓ crystal in accordance with the flash annealing scheme, a heating section may be used to preheat the entire base wafer 1280 in advance to a temperature of approximately 400° C. to 600° C. After preheating the base wafer 1280 from the side of the second main plane 1284, the thermal process apparatus 1200 may apply an electromagnetic wave to the base wafer 1280 from the side of the first main plane 1282 while maintaining the temperature of the entire base wafer 1280 at a prescribed temperature.

The thermal process apparatus 1200 may heat the base wafer 1280 in such a manner that the amount of the heat added to the entire base wafer 1280 by the heat source positioned below the base wafer 1280 is substantially equal to the amount of the heat emitted from the base wafer 1280. The thermal process apparatus 1200 can reduce the pulse amplitude of the electromagnetic wave by preheating the base wafer 1280.

The preheating is performed to such an extent that the temperature of the portion to be protected 140 does not exceed the temperature at which the portion to be protected 140 is thermally deteriorated. Here, the temperature at which the portion to be protected 140 is thermally deteriorated is defined as the temperature at which the characteristics of the portion to be protected 140 go beyond a designed acceptable range.

The preheating can be realized, for example, by heating, to a prescribed temperature, a support that supports the base wafer 1280 within the reaction chamber. For example, the support, which has been heated to a prescribed temperature, is brought into contact with the second main plane 1284 of the base wafer 1280, so that the portion to be thermally processed 130 and the portion to be protected 140 are preheated through the thermal conduction from the support to the base wafer 1280. The support is heated, for example, by applying an electromagnetic wave that is capable of being absorbed by the support to the first main plane 1282. Alternatively, the support may be eletrothermally heated by heater or the like. Referring to the preheating, the base wafer 1280 may be heated by applying an electromagnetic wave that is capable of being absorbed by the base wafer 1280 from the side of the second main plane 1284.

The lamp unit 1240 is shown as an exemplary heating section. The lamp unit 1240 is positioned so as to face the second main plane 1284 of the base wafer 1280. The lamp unit 1240 applies an electromagnetic wave to the base wafer 1280 from the side of the second main plane 1284 of the base wafer 1280. In this manner, the lamp unit 1240 can heat the support 1224. In addition, the lamp unit 1240 can heat the entire base wafer 1280 through the support 1224. The base wafer 1280 is heated, for example, through heat transfer from the support 1224.

Each lamp 1242 generates an electromagnetic wave. Each lamp 1242 generates, for example, light including infrared light. Each lamp 1242 may generate incoherent light. Thus, by arranging a large number of low-cost lamps 1242 in parallel, the base wafer 1280 having a large area can be thermally processed by a single operation. The lamps 1242 are each, for example, a high-intensity discharge lamp, a halogen lamp, a xenon lamp, or an LED lamp. The high-intensity discharge lamp is, for example, a high-pressure mercury lamp, a metal halide lamp, or a sodium lamp. It should be noted that the heating section is not limited to the lamp unit 1240. The heating section may wholly heat the support 1224 or the base wafer 1280 by means of resistance heating.

The thermal process apparatus 1200 may apply an electromagnetic wave using the lamps 1232 from above the base wafer 1280, while applying an electromagnetic wave using the lamp unit 1240. Keeping applying an electromagnetic wave using the lamp unit 1240, the thermal process apparatus 1200 can heat the portion to be thermally processed 130 while keeping the temperature of the back plane of the base wafer 1280 within a prescribed temperature range. This consequently facilitates the temperature control of the portion to be thermally processed 130.

The reflector 1244 reflects, among the electromagnetic waves applied from the lamps 1242, the electromagnetic waves that do not travel towards the base wafer 1280, toward the base wafer 1280. The power supply 1248 adjusts the currents supplied to the lamps 1242, for example, based on the signal received from the controller 1260.

The radiation thermometer 1252 measures the temperature of the base wafer 1280. The radiation thermometer 1252 is shown as an exemplary temperature measuring section. The radiation thermometer 1252 measures the radiant heat of the portion to be thermally processed 130 when the portion to be thermally processed 130, which is adapted to be heated by the electromagnetic wave applied from the lamp unit 1230, is formed in the vicinity of the front plane of the base wafer 1280. Thus, the temperature of the portion to be thermally processed 130 can be measured in a contactless manner. In addition, the radiation thermometer 1252 measures the temperature of the portion to be protected 140 in a contactless manner by measuring the radiant heat of the portion to be protected 140.

The radiation thermometer 1252 may measure the temperature of the base wafer 1280 or the like while the lamp unit 1230 is not applying an electromagnetic wave. In this way, the temperature of the base wafer 1280 or the like can be more accurately measured. The radiation thermometer 1252 may measure the temperature of the base wafer 1280 or the like immediately after the lamps 1232 go off. The radiation thermometer 1252 may sequentially measure the temperature of the portion to be protected 140 and the temperature of the portion to be thermally processed 130. For example, the radiation thermometer 1252 alternately measures the temperature of the portion to be protected 140 and the temperature of the portion to be thermally processed 130. The radiation thermometer 1252 may measure the temperature of the portion to be thermally processed 130 multiple times after measuring the temperature of the portion to be protected 140 multiple times.

The controller 1260 controls the lamp units 1230 and 1240 to adjust the temperature of the base wafer 1280. For example, the controller 1260 controls the current or the voltage supplied by the power supply 1238 to the lamps 1232 and the current or the voltage supplied by the power supply 1248 to the lamps 1242. The controller 1260 may control the lamp unit 1230 to apply, to the base wafer 1280, an electromagnetic wave that has been pulsed, after controlling the lamp unit 1240 to preheat the base wafer 1280 by continuously applying an electromagnetic wave to the support 1224.

The controller 1260 may control the lamp unit 1230 and the lamp unit 1240 independently from each other. The controller 1260 may control the outputs of the electromagnetic waves from the lamp units 1230 and 1240. For example, the controller 1260 controls how the lamp units 1230 and 1240 blink, how often they blink, the intensities of the generated electromagnetic waves, the average outputs, and the total doses of the applications over a prescribed duration, and other parameters.

In order that the lamp unit 1230 applies an electromagnetic wave that has been pulsed, the controller 1260 may control the lamp unit 1230 to establish an application period during which the lamp unit 1230 applies an electromagnetic wave and a non-application period during which the lamp unit 1230 does not apply an electromagnetic wave. Alternatively, in order that the lamp unit 1230 applies an electromagnetic wave that has been pulsed, the controller 1260 may control the lamp unit 1230 to establish a period during which the lamp unit 1230 applies an electromagnetic wave having a high output and a period during which the lamp unit 1230 applies an electromagnetic wave having a lower output than the above-mentioned electromagnetic wave.

The controller 1260 may control the output of the lamp unit 1240 based on the temperature of the support 1224, the temperature being measured by the temperature sensor disposed on the support 1224. The controller 1260 may control the output of the lamp unit 1230 based on the temperature measured by the radiation thermometer 1252. For example, the controller 1260 adjusts the intensity of the electromagnetic wave to be applied by the lamp unit 1230, based on the temperature of the portion to be thermally processed 130, the temperature being measured by the radiation thermometer 1252. For example, using the radiation thermometer 1252, the controller 1260 measures the temperature of the base wafer 1280, the temperature of the portion to be thermally processed 130, the temperature of the portion to be protected 140 and other temperatures during the non-application period of the lamp unit 1230.

When the measured temperature of the portion to be thermally processed 130 does not reach the temperature necessary for annealing, the controller 1260 may increase the width of the pulse output from the lamp unit 1230 to raise the temperature of the portion to be thermally processed 130. The controller 1260 may raise the temperature of the portion to be thermally processed 130 by increasing the duration of the application made by the lamp unit 1230. When the temperature of the portion to be protected 140 exceeds the maximum acceptable temperature of the portion to be protected 140, the controller 1260 may lower the temperature of the portion to be protected 140 by decreasing the width of the pulse output from the lamp unit 1230. Here, the maximum acceptable temperature is determined based on the temperature at which the portion to be protected 140 may deteriorate.

The controller 1260 may determine an application period during which the lamp unit 1230 applies an electromagnetic wave and a non-application period during which the lamp unit 1230 does not apply an electromagnetic wave, based on the result of the measurement done by the temperature sensor. Here, the temperature sensor serves as a heating temperature measuring section, and the lamp unit 1230 serves as an irradiating section. Specifically speaking, the controller 1260 controls the amount of the heat to be added by the lamp unit 1230, based on the temperature of the back plane of the base wafer 1280, the temperature being measured by the temperature sensor. For example, when the temperature of the back plane of the base wafer 1280 is 300° C., the controller 1260 sets the application period of the lamp unit 1230 longer than when the temperature of the back plane of the base wafer 1280 is 400° C. In this manner, the temperature of the portion to be thermally processed 130 can rise to the temperature necessary for annealing within a short period of time.

As discussed above, the thermal process apparatus 1200 can selectively heat the portion to be thermally processed 130 by applying an electromagnetic wave to thermally process the base wafer 1280 having the portion to be thermally processed 130, the portion to be protected 140, and the protective layer 150. This can reduce the density of the defects within the crystal of the portion to be thermally processed 130.

Having the lamp unit 1230 that heats the base wafer 1280 from the side of the first main plane 1282 and the lamp unit 1240 that heats the base wafer 1280 from the side of the second main plane 1284, the thermal process apparatus 1200 can heat the base wafer 1280 from both sides. In addition, the thermal process apparatus 1200 can control the lamp units 1230 and 1240 independently from each other and can thus heat the base wafer 1280 from the respective sides independently from each other. As a consequence, the thermal process apparatus 1200 can control the temperature of a wafer in various manners.

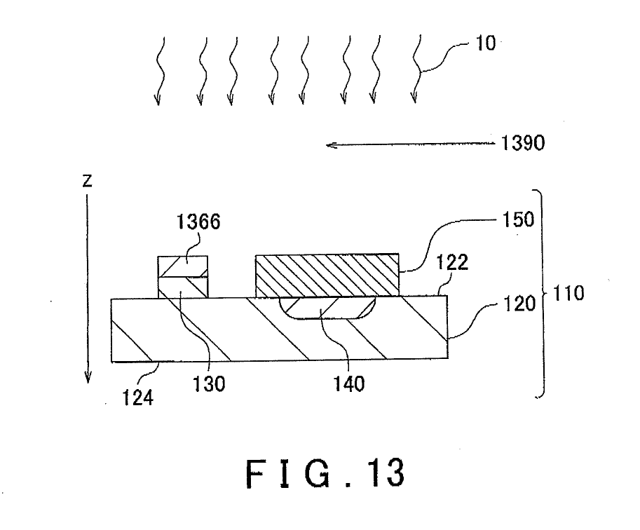

FIG. 13 schematically illustrates an exemplary cross-section of the semiconductor wafer 110. FIG. 13 is used to illustrate the method for epitaxially growing a group III-V compound semiconductor 1366 on the front plane of the portion to be thermally processed 130 of the semiconductor wafer 110 described with reference to FIG. 1. The group III-V compound semiconductor 1366 is shown as an exemplary group III-V compound semiconductor.

The group III-V compound semiconductor 1366 can be formed, for example, in the following manner. To begin with, the semiconductor wafer 110 is provided that has the portion to be thermally processed 130, the portion to be protected 140, and the protective layer 150. The semiconductor wafer 110 is held, for example, within a reaction chamber of a CVD apparatus.

After this, while the electromagnetic wave 10 that is capable of being absorbed by the portion to be thermally processed 130 is applied to the entire semiconductor wafer 110, a source gas 1390 is supplied to the reaction chamber. When the electromagnetic wave 10 is applied to the semiconductor wafer 110, the portion to be thermally processed 130 is selectively heated. As a result, on the Front plane of the heated portion to be thermally processed 130, the group III-V compound semiconductor 1366 is selectively epitaxially grown. Here, the electromagnetic wave 10 may be applied to the semiconductor wafer 110 while the entire semiconductor wafer 110 is heated from the side of the second main plane 124.

The portion to be thermally processed 130 may be annealed prior to the step of epitaxially growing the group III-V compound semiconductor 1366. This annealing is performed, for example, using the electromagnetic wave that is used to selectively heat the portion to be thermally processed, the electromagnetic wave being described with reference to FIGS. 1 to 11. Here, the heating of the portion to be thermally processed may be performed within the same reaction chamber as the epitaxial growth of the group III-V compound semiconductor 1366. Furthermore, the epitaxial growth of the group III-V compound semiconductor 1366 may be performed successively alter the heating of the portion to be thermally processed without exposing the semiconductor wafer 110 to air between the heating and the epitaxial growth. The protective layer 150 may be replaced with the protective layer 250 described with reference to FIG. 2.

The method for selectively epitaxially growing the group III-V compound semiconductor 1366 on the front plane of the portion to be thermally processed 130 is not limited to the above-described method. A wafer having a portion to be thermally processed and a heat generating section that generates heat through the absorption of an electromagnetic wave and selectively heats the portion to be thermally processed may be provided, and an electromagnetic wave that is capable of being absorbed by the heat generating section may be applied to the wafer. In this case, the group III-V compound semiconductor can be epitaxially grown on the front plane of the heated portion to be thermally processed by supplying the source gas 1390 to the reaction chamber.

According to another exemplary method for selectively epitaxially growing the group III-V compound semiconductor 1366 on the front plane of the portion to be thermally processed 130, a portion to be thermally processed including a SiₓGe₁₋ₓ crystal (0≦x<1) is formed on a base wafer that is selected among an SOI wafer and a Si wafer, the base wafer having at least a portion of a semiconductor device formed thereon. In the case of this method, an electromagnetic wave for which the SiₓGe₁₋ₓ crystal has a higher absorption coefficient than the Si included in the base wafer is applied to the wafer to heat the SiₓGe₁₋ₓ crystal. While this electromagnetic wave is applied, the source gas 1390 is supplied to the reaction chamber. In this way, the group III-V compound semiconductor may be epitaxially grown on the front plane of the heated portion to be thermally processed.

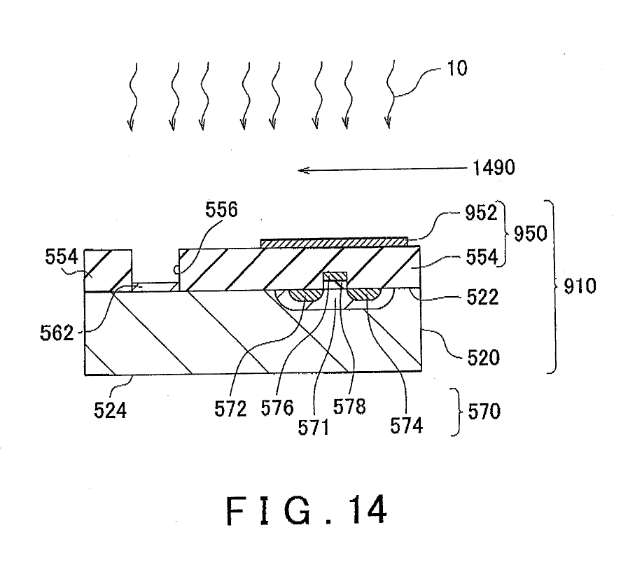

FIG. 14 schematically illustrates the exemplary semiconductor wafer 910 observed during the production process of the semiconductor wafer 510. FIG. 14 is used to illustrate an exemplary method for epitaxially growing the group III-V compound semiconductor 566 on the semiconductor wafer 910 that is produced in the method described with reference to FIG. 10. As shown in FIG. 14, the semiconductor wafer 910 has the SiₓGe₁₋ₓ crystal 562, which is obtained by heating the SiₓGe₁₋ₓ crystal 962. The semiconductor wafer 910 has the protective layer 950.

The group III-V compound semiconductor 566 can be formed, for example, in the following manner. To begin with, the semiconductor wafer 910, which has the SiₓGe₁₋ₓ crystal 562 formed thereon, is held within a reaction chamber of a CVD apparatus. The thermal process apparatus used to heat the SiₓGe₁₋ₓ crystal 962 may also serve as the CVD apparatus.

After this, while the electromagnetic wave 10 that is capable of being absorbed by the SiₓGe₁₋ₓ crystal 562 is applied to the entire semiconductor wafer 910, a source gas 1490 is supplied to the reaction chamber. Following this, the thermal process apparatus applies the electromagnetic wave 10 to the semiconductor wafer 910. The electromagnetic wave 10 selectively heats the SiₓGe₁₋ₓ crystal 562, so that the group III-V compound semiconductor 566 is selectively epitaxially grown on the front plane of the heated SiₓGe₁₋ₓ crystal 562. Here, the thermal process apparatus may apply the electromagnetic wave 10 to the semiconductor wafer 910 while heating the entire semiconductor wafer 910 from the side of the second main plane 524.

The method for selectively epitaxially growing the group III-V compound semiconductor 566 is not limited to the above-described method. A heat generating layer may be provided within the inhibition layer 554 in the vicinity of the SiₓGe₁₋ₓ crystal layer 562. In this way, while selectively heating the SiₓGe₁₋ₓ crystal layer 562, the source gas 1490 may be supplied to the reaction chamber. The semiconductor wafer 910 may have the heat generating layer and the protective layer 950.

### EXEMPLARY EMBODIMENTS

### Exemplary Embodiment 1

The electronic device 500 was produced in accordance with the procedure shown in FIG. 6. As the base wafer 520, a commercially available SOI wafer was provided. As the first electronic element 570, which is shown as an exemplary portion to be protected, a MOSFET was formed in the Si crystal layer of the base wafer 520. As the inhibition layer 554, a SiO₂ layer in contact with the first main plane 522 of the base wafer 520 was formed by CVD. The average thickness of the SiO₂ layer was 1 μm. The opening 556 was formed in a part of the inhibition layer 554 by photolithography. The opening 556 had a size of 15 μm×15 μm.

The base wafer 520 on which the inhibition layer 554 and the opening 556 had been formed was arranged within the thermal process furnace 1210 of the thermal process apparatus 1200 to form a Ge crystal layer as the SiₓGe₁₋ₓ crystal 962. The base wafer 520 was placed on the upper plane of the support 1224 in such a manner that the second main plane 524 of the base wafer 520 came into contact with the support 1224. The support 1224 was a graphite susceptor. The Ge crystal layer was selectively formed within the opening 556 by CVD. The Ge crystal layer was first deposited until the thickness became approximately 20 nm using GeH₄ as the source gas with the pressure within the thermal process furnace 1210 being set at 2.6 kPa and the temperature being set at 400° C. After this, the temperature was raised to 600° C., and the Ge crystal layer was further deposited until the thickness became approximately 1 μm.

As the block layer 952, a structure constituted by an Ag thin film and a SiO₂ layer was formed. This structure was formed in the Following manner. The Ag thin film was formed in advance on the front plane of the inhibition layer 554 by vacuum evaporation. Furthermore, after the SiO₂ layer having the thickness of 100 nm was deposited as an Ag protecting layer by vacuum evaporation on the front plane of the Ag thin film, the Ag thin film and the SiO₂ layer, which served as the Ag protecting layer, were patterned by photolithography. In this way, the structure was obtained. The Ag thin film and the SiO₂ layer, which served as the Ag protecting layer, were patterned to be sized so as to cover and hide the first electronic element 570 when seen in the perpendicular direction to the first main plane 522. In the above-described steps, the semiconductor wafer 910 was produced.

Subsequently, within the thermal process furnace 1210, the lamp unit 1240 applied an infrared ray toward the hack plane of the support 1224, on which the semiconductor wafer 910 was placed. In this manner, the support 1224 was heated. By means of the thermal conduction from the support 1224 to the second main plane 524 of the semiconductor wafer 910, the semiconductor wafer 910 was preheated. The preheating was performed to such an extent that the temperature of the support 1224 became 400° C. Here, the temperature of approximately 400° C. was also observed in the vicinity of the SiₓGe₁₋ₓ crystal 962 and in the vicinity of the first electronic element 570.

The temperatures were measured using an infrared surface thermometer. After the temperature of the semiconductor wafer 910 was stabilized by the preheating, while the lamp unit 1240 was heating the entire semiconductor water 910, the lamp unit 1230 applied lamp light including an infrared ray to the semiconductor wafer 910 from the side of the first main plane 522 with the inhibition layer 554 and the block layer 952 being used as the protective layer. In this way, the SiₓGe₁₋ₓ crystal 962 was selectively heated and thus annealed.

After the SiₓGe₁₋ₓ crystal 962 was formed, the semiconductor wafer 910 was not taken out of the thermal process furnace 1210 before the irradiation of the lamp light started. Stated differently, in the present exemplary embodiment, after the step of growing the precursors of the SiₓGe₁₋ₓ crystal 962 into a crystal, the step of selectively heating the SiₓGe₁₋ₓ crystal 962 was successively performed without exposing the SiₓGe₁₋ₓ crystal 962 to air between the steps. In addition, the step of growing the precursors of the SiₓGe₁₋ₓ crystal 962 into a crystal was performed within the same reaction chamber as the step of selectively heating the SiₓGe₁₋ₓ crystal 962.

The above-mentioned lamp light including an infrared ray was emitted from a light source using 20 halogen lamps each having the maximum output of 1.6 kW (available from USHIO INC.). The outputs of the halogen lamps were adjusted in the following manner. To start with, a reference wafer was provided in which a Ge single-crystal layer having the thickness of approximately 1 μm was formed on the entire plane or a Si wafer. Using the reference wafer, the correlation characteristics between the outputs of the halogen lamps and the surface temperature of the reference wafer were obtained. Based on the obtained correlation characteristics, the outputs of the halogen lamps were set so that the surface temperature of the first main plane 522 of the semiconductor wafer 910 became 850° C., and the lamp light was applied to the semiconductor wafer 910 for 20 minutes. Between the halogen lamps and the semiconductor wafer 910, a Si single-crystal plate was disposed as the filter 1236. Thus, the light that had transmitted through the Si single-crystal plate was applied to the first main plane 522 of the semiconductor wafer 910.

The correlation characteristics between the outputs of the halogen lamps and the surface temperature of the reference wafer were obtained in the following manner. To start with, the reference wafer was placed on the support 1224 within the thermal process furnace 1210. The reference wafer was placed in such a manner that the plane (may be referred to as a second main plane) that faced away from the plane on which the Ge single-crystal layer was formed (may be referred to as a first main plane) came into contact with the upper plane of the support 1224.

After this, the reference wafer was preheated. The preheating was performed in such a manner that, within the thermal process furnace 1210, the an infrared ray was applied to the support 1224 from the side of the lower plane to heat the support 1224. By means of the thermal conduction from the support 1224 to the reference wafer, the entire reference wafer was heated. The preheating was performed to such an extent that the temperature of the support 1224 became 400° C. Here, calibration of the infrared surface thermometer was also carried out. According to the calibration, the setting of the infrared surface thermometer was adjusted such that the infrared surface thermometer read approximately 400° C. when measuring the surface temperature of the first main plane of the reference wafer.

After the temperature of the reference wafer was stabilized by the preheating, the lamp light including an infrared ray was applied to the reference wafer from the side of the first main plane of the reference wafer intermittently at intervals of approximately 10 seconds. By measuring the surface temperature of the first main plane immediately after the lamp light went off with the infrared surface thermometer, the correlation characteristics between the outputs of the halogen lamps that were applied from the side of the first main plane and the surface temperature of the first main plane of the reference wafer were obtained.

While the lamp light was applied to the semiconductor wafer 910 and the reference wafer, the temperature of the support 1224 was adjusted in such a manner that a thermocouple embedded within the support 1224 was used to detect the temperature of the support 1224 and the energy of the infrared ray applied to the lower plane of the support 1224 was feedback-controlled. The energy of the infrared ray was adjusted so that the temperature of the support 1224 became 400° C.

As described above, after the SiₓGe₁₋ₓ crystal 962 of the semiconductor wafer 910 was annealed, a GaAs layer was formed by MOCVD as the group III-V compound semiconductor 566 without removing the semiconductor wafer 910 from the thermal process furnace 1210 between the annealing and the GaAs layer formation. The GaAs layer was deposited using trimethyl gallium and arsine as the source gases with the temperature being set at 650° C. and the pressure within the thermal process furnace 1210 being set at 9.9 kPa. The GaAs layer was formed by supplying the source gases into the thermal process furnace 1210 while the electromagnetic wave that was capable of being absorbed by the SiₓGe₁₋ₓ crystal 562, which was obtained as a result of the annealing, was applied to the semiconductor wafer 910. The GaAs layer was formed while the lamp unit 1240 was heating the entire semiconductor wafer 910. Here, the temperature of the graphite support was adjusted to become 400° C. After this, the outermost SiO₂ layer, which served as the Ag protecting layer, and the Ag thin film were removed by etching. As a result, the semiconductor wafer 510 was produced.

As the second electronic element 580, a HBT whose active layer was formed by the GaAs layer was formed. After this, interconnections were formed. As a result, the electronic device 500 was produced. An operational test performed on the electronic device 500 confirmed that the electronic device 500 showed a current gain of 181 for a collector current density of 1 kA/cm². Thus, the electronic device 500 was confirmed that it could operate normally as a current amplifying element. The MOSFET, which was formed in the Si crystal layer of the base wafer 520 as the first electronic element 570, was confirmed that the threshold value and the current-voltage characteristics remained unchanged from the initial characteristics.

Furthermore, observation of the annealed Ge crystal layer using an SEM revealed that the Ge crystal layer had the thickness of approximately 1 μm and the GaAs layer had the thickness of 2.5 μm as designed. Examination of the front plane of the GaAs layer using the etch-pit method found no defects on the front plane of the GaAs layer. In-plane cross-sectional observation using a TEM found no dislocations that penetrated through the Ge crystal layer and the GaAs layer.

### Exemplary Embodiment 2

The electronic device 500 was produced in accordance with the procedure shown in FIG. 6. As in Exemplary Embodiment 1, the inhibition layer 554 and the opening 556 were formed on the base wafer 520. The base wafer 520 was arranged within the thermal process furnace 1210 to form a Ge crystal layer as the SiₓGe₁₋ₓ crystal 962. The Ge crystal layer was selectively formed within the opening 556 by CVD. The Ge crystal layer was first deposited until the thickness became approximately 20 nm using GeH₄ as the source gas with the pressure within the thermal process furnace 1210 being set at 2.6 kPa and the temperature being set at 400° C. Alter this, the temperature was raised to 600° C., and the Ge crystal layer was further deposited until the thickness became approximately 1 μm.

As the block layer 952, a structure constituted by an Ag thin film and a SiO₂ layer was formed. This structure was formed in the following manner. The Ag thin film was formed in advance on the front plane of the inhibition layer 554 by vacuum evaporation. Furthermore, after the SiO₂ layer having the thickness of 100 nm was deposited as an Ag protecting layer by vacuum evaporation on the front plane of the Ag thin film, the Ag thin film and the SiO₂ layer, which served as the Ag protecting layer, were patterned by photolithography. In this way, the structure was obtained. The Ag thin film and the SiO₂ layer, which served as the Ag protecting layer, were patterned to be sized so as to cover and hide the first electronic element 570 when seen in the perpendicular direction to the first main plane 522. In the above-described steps, the semiconductor wafer 910 was produced.

Subsequently, the semiconductor wafer 910 was taken out of the thermal process furnace 1210, and placed on a graphite support that is positioned within a different reaction chamber in such a manner that the second main plane 524 of the base wafer 520 came into contact with the graphite support. Within, this different reaction chamber, the graphite support was thermoelectrically heated from the side of the back plane of the graphite support on which the semiconductor wafer 910 was placed. As a result, the semiconductor wafer 910 was preheated by means of the thermal conduction to the second main plane 524 of the semiconductor wafer 910, the second main plane 524 being in contact with the graphite support. The preheating was performed to such an extent that the temperature of the graphite support reached 200° C. to 600° C.

After the temperature of the semiconductor wafer 910 was stabilized by the preheating, while the lamp unit 1240 was heating the entire semiconductor wafer 910, a flash was applied to the semiconductor wafer 910 from the side of to the first main plane 522 under an inert gas atmosphere of N₂ or Ar with the inhibition layer 554 and the block layer 952 being used as the protective layer. In this way, the SiₓGe₁₋ₓ crystal 962 was selectively heated and thus annealed.

As the flash lamp, a xenon lamp whose input energy per unit area of the semiconductor wafer 910 reached approximately 15 J/cm² (available from USHIO INC.) was used. The flash was applied in five pulses with the pulse width being set at 1 ms and the interval between the pulses being set at 30 s. Here, the temperature of the graphite support was adjusted to become equal to 400° C. Between the flash lamp and the semiconductor wafer 910, a Si single-crystal plate was disposed as the filter 1236. Thus, the light that had transmitted through the Si single-crystal plate was applied to the first main plane 522 of the semiconductor wafer 910.

As described above, after the SiₓGe₁₋ₓ crystal 962 of the semiconductor wafer 910 was annealed, the semiconductor wafer 910 was taken out of the reaction chamber in which the thermal processing was performed. After this, using a different reaction chamber, a GaAs layer was formed by MOCVD as the group III-V compound semiconductor 566. The GaAs layer was deposited using trimethyl gallium and arsine as the source gases with the temperature being set at 650° C. and the pressure within the reaction chamber being set at 9.9 kPa.

The GaAs layer was formed by supplying the source gases into the thermal process furnace 1210 while the electromagnetic wave that was capable of being absorbed by the SiₓGe₁₋ₓ crystal 562, which was obtained as a result of the annealing, was applied to the semiconductor wafer 910. The GaAs layer was formed while the lamp unit 1240 was heating the entire semiconductor wafer 910. Here, the temperature of the graphite support was adjusted to become 400° C. After this, the outermost SiO₂ layer, which served as the Ag protecting layer, and the Ag thin film were removed by etching. As a result, the semiconductor wafer 510 was produced.

As the second electronic element 580, a HBT whose active layer was formed by the GaAs layer was formed. After this, interconnections were formed. As a result, the electronic device 500 was produced. An operational test performed on the electronic device 500 confirmed that the electronic device 500 showed a current gain of 178 for a collector current density of 1 kA/cm². Thus, the electronic device 500 was confirmed that it could operate normally as a current amplifying element. The MOSFET, which was formed in the Si crystal layer of the base wafer 520 as the first electronic element 570, was confirmed that the threshold value and the current-voltage characteristics remained unchanged from the initial characteristics.

Furthermore, observation of the annealed Ge crystal layer using an SEM revealed that the Ge crystal layer had the thickness of approximately 1 μm and the GaAs layer had the thickness of approximately 2.5 μm as designed. Examination of the front plane of the GaAs layer using the etch-pit method found no defects on the front plane of the GaAs layer. In-plane cross-sectional observation using a TEM found no dislocations that penetrated through the Ge crystal layer and the GaAs layer.

### Exemplary Embodiment 3

The electronic device 500 was produced in accordance with the procedure shown in FIG. 6. As the base wafer 520, a commercially available Si wafer was provided. As the electronic element 570, which was shown as an exemplary portion to be protected, a MOSFET was formed in the Si crystal layer of the base wafer 520. As the inhibition layer 554, a SiO₂ layer in contact with the first main plane 522 of the base wafer 520 was formed by CVD. The average thickness of the SiO₂ layer was 1 μm. The opening 556 was formed in a part of the inhibition layer 554 by photolithography. The opening 556 had a size of 15 μm×15 μm.

The base wafer 520 on which the inhibition layer 554 and the opening 556 had been formed was arranged within the thermal process furnace 1210 of the thermal process apparatus 1200 to form a Ge crystal layer as the SiₓGe₁₋ₓ crystal 962. The base wafer 520 was placed on the upper plane of the support 1224 in such a manner that the second main plane 524 of the base wafer 520 came into contact with the support 1224. The support 1224 was a graphite susceptor. The Ge crystal layer was selectively formed within the opening 556 by CVD. The Ge crystal layer was first deposited until the thickness became approximately 20 nm using GeH₄ as the source gas with the pressure within the thermal process furnace 1210 being set at 2.6 kPa and the temperature being set at 400° C. After this, the temperature was raised to 600° C., and the Ge crystal layer was further deposited until the thickness became approximately 1 μm.

As the block layer 952, a structure constituted by an Ag thin film and a SiO₂ layer was formed. This structure was formed in the following manner. The Ag thin film was formed in advance on the front plane of the inhibition layer 554 by vacuum evaporation. Furthermore, after the SiO₂ layer having the thickness of 100 nm was deposited as an Ag protecting layer by vacuum evaporation on the front plane of the Ag thin film, the Ag thin film and the SiO₂ layer, which served as the Ag protecting layer, were patterned by photolithography. The Ag thin film and the SiO₂ layer, which served as the Ag protecting layer, were patterned to be sized so as to cover and hide the electronic element 570 when seen in the perpendicular direction to the first main plane 522. In the above-described steps, the semiconductor wafer 910 was produced.

Subsequently, within the thermal process furnace 1210, the lamp unit 1240 applied an infrared ray toward the back plane of the support 1224, on which the semiconductor wafer 910 was placed. in this manner, the support 1224 was heated. By means of the thermal conduction from the support 1224 to the second math plane 524 of the semiconductor wafer 910, the semiconductor wafer 910 was preheated. The preheating was performed to such an extent that the temperature of the support 1224 became 400° C. Here, the temperature of approximately 400° C. was also observed in the vicinity of the SiₓGe₁₋ₓ crystal 962 and in the vicinity of the electronic element 570. The temperatures were measured using an infrared surface thermometer.

After the temperature of the semiconductor wafer 910 was stabilized by the preheating, while the lamp unit 1240 was heating the entire semiconductor wafer 910, the lamp unit 1230 applied lamp light including an infrared ray to the semiconductor wafer 910 from the side of the first main plane 522 with the inhibition layer 554 and the block layer 952 being used as the protective layer. In this way, the SiₓGe₁₋ₓ crystal 962 was selectively heated and thus annealed.

After the SiₓGe₁₋ₓ crystal 962 was formed, the semiconductor wafer 910 was not taken out of the thermal process furnace 1210 before the application of the lamp light started. Stated differently, in the present exemplary embodiment, after the step of growing the precursors of the SiₓGe₁₋ₓ crystal 962 into a crystal, the step of selectively heating the SiₓGe₁₋ₓ crystal 962 was successively performed without exposing the SiₓGe₁₋ₓ crystal 962 to air between the steps. In addition, the step of growing the precursors of the SiₓGe₁₋ₓ crystal 962 into a crystal was performed within the same reaction chamber as the step of selectively heating the SiₓGe₁₋ₓ crystal 962.

The above-mentioned lamp light including an infrared ray was emitted from a light source using 20 halogen lamps each having the maximum output of 1.6 kW (available from USHIO INC.). The outputs of the halogen lamps were adjusted in the following manner. To start with, a reference wafer was provided in which a Ge single-crystal layer having the thickness of approximately 1 μm was formed on the entire plane of a Si wafer. Using the reference wafer, the correlation characteristics between the outputs of the halogen lamps and the surface temperature of the reference wafer were obtained. Based on the obtained correlation characteristics, the outputs of the halogen lamps were set so that the surface temperature of the first main plane 522 of the semiconductor wafer 910 became 850° C., and the lamp light was directly applied to the first main plane 522 of the semiconductor wafer 910 for 20 minutes without positioning the filter 1236 between the halogen lamps and the first main plane 522.

The correlation characteristics between the outputs of the halogen lamps and the surface temperature of the reference wafer were obtained in the following manner. To start with, the reference wafer was placed on the support 1224 within the thermal process furnace 1210. The reference wafer was placed in such a manner that the plane (may be referred to as a second main plane) that faced away from the plane on which the Ge single-crystal layer was formed (may be referred to as a first main plane) came into contact with the upper plane of the support 1224.

After this, the reference wafer was preheated. The preheating was performed in such a manner that, within the thermal process furnace 1210, the an infrared ray was applied to the support 1224 from the side of the lower plane to heat the support 1224. By means of the thermal conduction from the support 1224 to the reference wafer, the entire reference wafer was heated. The preheating was performed to such an extent that the temperature of the support 1224 became 400° C. Here, calibration of the infrared surface thermometer was also carried out. According to the calibration, the setting of the infrared surface thermometer was adjusted such that the infrared surface thermometer read approximately 400° C. when measuring the surface temperature or the first main plane of the reference wafer.

After the temperature of the reference wafer was stabilized by the preheating, the lamp light including an infrared ray was applied to the reference wafer from the side of the first main plane of the reference wafer intermittently at intervals of approximately 10 seconds. By measuring the surface temperature of the first main plane immediately after the lamp light went off with the infrared surface thermometer, the correlation characteristics between the outputs of the halogen lamps that were applied from the side of the first main plane and the surface temperature of the first main plane of the reference wafer were obtained.

While the lamp light was applied to the semiconductor wafer 910 and the reference wafer, the temperature of the support 1224 was adjusted in such a manner that a thermocouple embedded within the support 1224 was used to detect the temperature of the support 1224 and the energy of the infrared ray applied to the lower plane of the support 1224 was feedback-controlled. The energy of the infrared ray was adjusted so that the temperature of the support 1224 became 400° C. After the SiₓGe₁₋ₓ crystal 962 of the semiconductor wafer 910 was annealed, the semiconductor wafer 910 was taken out of the thermal process furnace 1210.

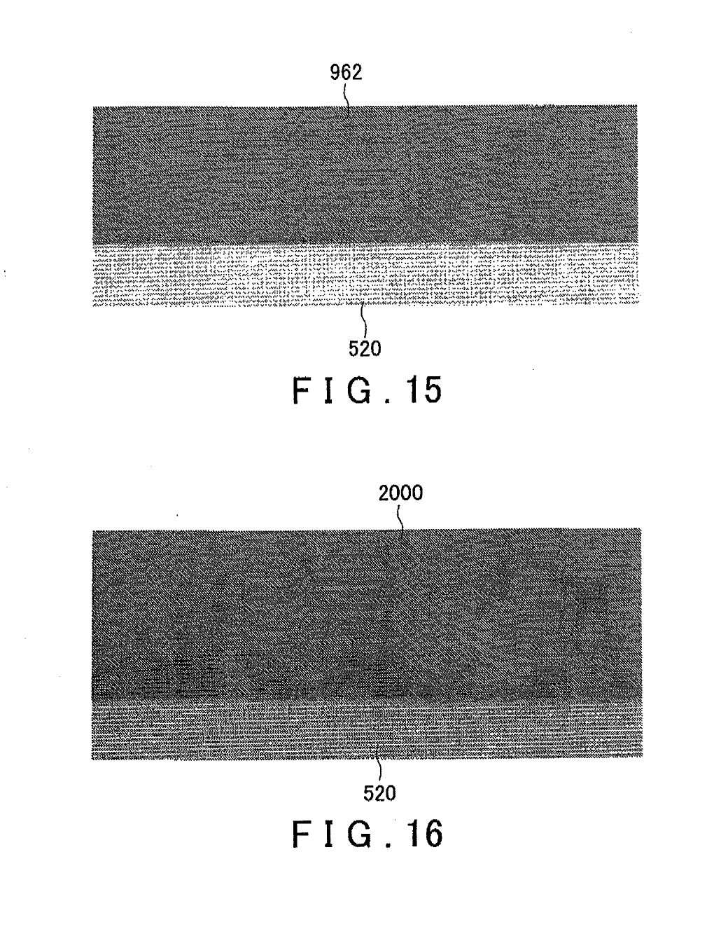

FIG. 15 is a TEM photograph showing the cross-section of the semiconductor wafer 910, which has been taken out of a thermal process furnace 1210. The boundary portion between the base wafer 520 and the SiₓGe₁₋ₓ crystal 962 formed thereon was examined. FIG. 16 is a TEM photograph showing the cross-section of the semiconductor wafer 910 including a SiₓGe₁₋ₓ crystal 2000, which has not been thermally processed. Unlike the SiₓGe₁₋ₓ crystal 962, the SiₓGe₁₋ₓ crystal 2000 shown in FIG. 16 is not annealed. Many dislocations were found in the SiₓGe₁₋ₓ crystal 2000. Comparing FIGS. 15 and 16 with each other clearly indicates that no dislocations are in the annealed SiₓGe₁₋ₓ crystal 962.

### Exemplary Embodiment 4

The semiconductor wafer 510 was produced as in Exemplary Embodiment 1 except that the base wafer 520 was a commercially available Si wafer and the electronic element 570 was omitted. As the electronic element 580, a HBT whose active layer was formed using the GaAs layer was formed. Furthermore, interconnections to be connected to the collector, base, and emitter of the HBT were formed. As a result, the electronic device 500 was obtained.

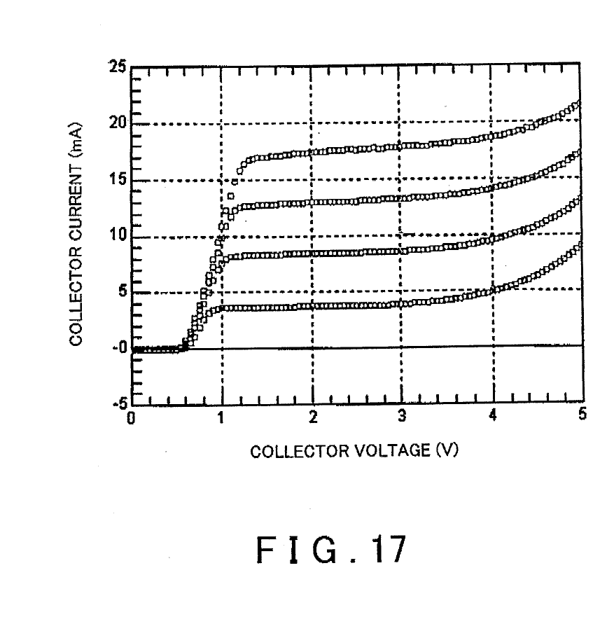

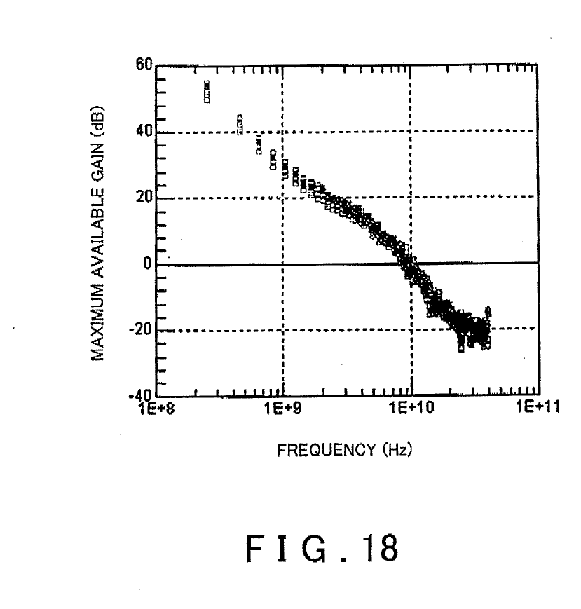

FIG. 17 shows how the collector current of the HBT fabricated as described above varies depending on the collector voltage of the HBT. FIG. 17 shows four different data sequences obtained by setting the base voltage at various values. FIG. 17 indicates that the collector current remained stable within a broad range of the collector voltage. FIG. 18 shows experimental data to determine such a maximum oscillation frequency that the current gain takes a value of 1. When the base-emitter voltage was 1.6 V, the maximum oscillation frequency took a value of 9 GHz. In other words, the fabricated HBT had superior current-voltage characteristics and superior high-frequency characteristics.

### Exemplary Embodiment 5

The semiconductor wafer 510 was produced as in Exemplary Embodiment 1 except that the base wafer 520 was a commercially available Si wafer, the electronic element 570 was omitted, and the pressure within the thermal process furnace 1210 was set to 0.5 kPa when the GaAs layer was formed as the group III-V compound semiconductor 566 was formed.

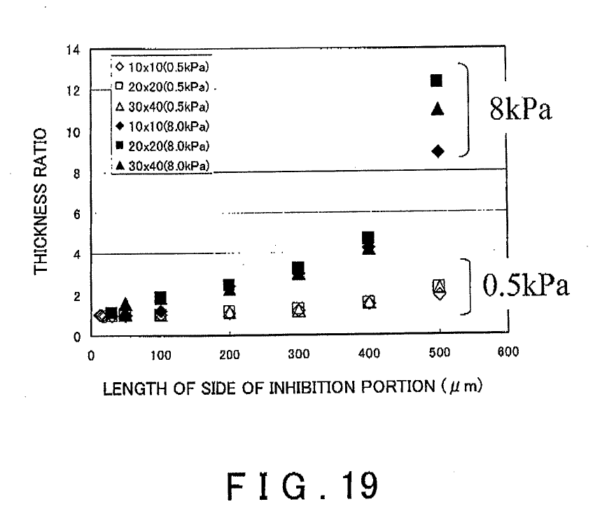

FIG. 19 shows how the growth rate of the group III-V compound semiconductor 566 is dependent on the size of a covering region and the size of the opening 556. In the drawing, the vertical axis represents the ratio between the thickness of the compound semiconductor 466 grown within a prescribed period of time with the covering region and the thickness of the compound semiconductor 466 grown within the prescribed period of time without the covering region, and the horizontal axis represents the length of each side of the covering region (inhibition portion) [μm]. In the present exemplary embodiment, since the thickness of the group III-V compound semiconductor 566 is defined as the thickness of the group III-V compound semiconductor 566 grown within the prescribed period of time, the result of dividing the thickness by the prescribed period of time indicates an approximate growth rate of the group III-V compound semiconductor 566.

In the drawing, the diamond marks represent the data resulting from the experiment in which the bottom of the opening 556 is shaped as a square with a side of 10 μm, and the square marks represent the data resulting from the experiment in which the bottom of the opening 556 is shaped as a square with a side of 20 μm. In the drawing, the triangular marks represent the data resulting from the experiment in which the bottom of the opening 556 is shaped as a rectangle with a long side of 40 μm and a short side of 30 μm. For the comparison purpose, the data sequences obtained from the experiments in which the pressure was set at 8 kPa are shown by black diamond, square, and triangular marks,

FIG. 19 shows that the growth rate of the group III-V compound semiconductor 566 monotonically increases as the size of the covering region increases and that the relation is weakened by lowering the pressure at which the growth takes place. This indicates that the pressure is preferably set low when the group III-V compound semiconductor 566 is grown on a wafer in which the openings and the covering regions have varying sizes. The pressure is preferably set at 1 kPa or lower, more preferably, at 0.5 kPa or lower.

Although some aspects of the present invention have been described by way of exemplary embodiments, it should be understood that those skilled in the art might make many changes and substitutions without departing from the spirit and the scope of the present invention which is defined only by the appended claims.

The claims, specification and drawings describe the processes of an apparatus, a system, a program and a method by using the terms such as operations, procedures, steps and stages. When a reference is made to the execution order of the processes, wording such as “before” or “prior to” is not explicitly used. The processes may be performed in any order unless an output of a particular process is used by the following process. In the claims, specification and drawings, a flow of operations may be explained by using the terms such as “first” and “next” for the sake of convenience. This, however, does not necessarily indicate that the operations should be performed in the explained order.

### DESCRIPTION OF REFERENCE NUMERALS

10 electromagnetic wave, 32 dotted line, 34 solid line, 36 solid line, 110 semiconductor wafer, 120 base wafer, 122 first main plane, 124 second main plane, 130 portion to be thermally processed, 140 portion to be protected, 150 protective layer, 210 semiconductor wafer, 250 protective layer, 252 block layer, 254 thermal conduction restraining layer, 257 front plane, 258 front plane, 259 back plane, 410 semiconductor wafer, 420 base wafer, 422 first main plane, 424 second main plane, 426 inhibition layer, 428 opening, 432 region, 434 region, 440 active region, 450 protective layer, 452 gate electrode, 454 gate insulator, 462 seed crystal, 466 compound semiconductor, 480 semiconductor device, 500 electronic device, 510 semiconductor wafer, 520 base wafer, 522 first main plane, 524 second main plane, 554 inhibition layer, 556 opening, 562 SiₓGe₁₋ₓ crystal, 566 group III-V compound semiconductor, 570 electronic element, 571 well, 572 source region, 574 drain region, 576 gate electrode, 578 gate insulator, 580 electronic element, 587 input/output electrode, 588 input/output electrode, 589 gate electrode, 592 interconnection, 593 opening, 594 interconnection, 595 opening, 596 interconnection, 910 semiconductor wafer, 950 protective layer, 952 block layer, 962 SiₓGe₁₋ₓ crystal, 1200 thermal process apparatus, 1210 thermal process furnace, 1212 wafer loading opening, 1214 gas inlet, 1216 gas outlet, 1222 flap, 1224 support, 1230 lamp unit, 1232 lamp, 1234 reflector, 1236 filter, 1238 power supply, 1240 lamp unit, 1242 lamp, 1244 reflector, 1248 power supply, 1260 controller, 1252 radiation thermometer, 1280 base wafer, 1282 first main plane, 1284 second main plane, 1290 source gas, 1366 group III-V compound semiconductor, 1390 source gas, 1490 source gas, 2000 SiₓGe₁₋ₓ crystal

1. A method of producing a semiconductor wafer by thermally processing a base wafer having a portion to be thermally processed that has a single-crystal layer and is to be subjected to a thermal processing and a portion to be protected that is to be protected from heat to be added during the thermal processing, the method comprising:
a step of forming, above the portion to be protected, a protective layer for protecting the portion to be protected from an electromagnetic wave to be applied to the base wafer; and
a step of annealing the portion to be thermally processed, by applying the electromagnetic wave to the portion to be thermally processed and the portion to be protected of the base wafer.

2. The method as set forth in claim 1 of producing a semiconductor wafer, further comprising a step of forming, as the portion to be protected, an electronic element in the base wafer.

3. The method as set forth in claim 1 of producing a semiconductor wafer, further comprising
a step of forming, as the portion to be protected, an active region of an electronic element in the base wafer.

4. The method as set forth in claim 2 of producing a semiconductor wafer, wherein
the electronic element comprises a silicon device.

5. The method as set forth in claim 1 of producing a semiconductor wafer, further comprising, prior to the step of forming a protective layer, a step of forming a metal interconnection as the portion to be protected, wherein
in the step of forming a protective layer, the protective layer is formed above the metal interconnection.

6. The method as set forth in claim 5 of producing a semiconductor wafer, wherein
the step of forming a metal interconnection comprises forming a plurality of metal interconnections and an insulating film that insulates between the metal interconnections from each other.

7. The method as set forth in claim 5 of producing a semiconductor wafer, wherein
the metal interconnection comprises Al.

8. The method as set forth in claim 7 of producing a semiconductor wafer, wherein
in the step of annealing, a temperature of the metal interconnection is maintained at or lower than 650° C.

9. The method as set forth in claim 1 of producing a semiconductor wafer, further comprising a step of forming, in the base wafer, the portion to be thermally processed comprising a SiₓGe₁₋ₓ crystal (0≦x<1).

10. The method as set forth in claim 9 of producing a semiconductor wafer, further comprising, after the step of annealing, a step of forming, by crystal growth, a group III-V compound semiconductor that has a lattice match or a pseudo lattice match with the SiₓGe₁₋ₓ crystal (0≦x<1).

11. The method as set forth in claim 10 of producing a semiconductor wafer, wherein
in the step of annealing, the portion to be thermally processed is annealed without exposing the base wafer to air after the step of forming a portion to be thermally processed.

12. The method as set forth in claim 11 of producing a semiconductor wafer, wherein
the step of forming a portion to be thermally processed and the step of annealing are performed within a same reaction chamber.

13. The method as set forth in claim 10 of producing a semiconductor wafer, wherein
in the step of forming a group III-V compound semiconductor by crystal growth, the electromagnetic wave is applied again to the base wafer by using the light source that applied the electromagnetic wave in the step of annealing.

14. The method as set forth in claim 1 of producing a semiconductor wafer, wherein
in the step of annealing, the electromagnetic wave is uniformly applied to the entire base wafer.

15. The method as set forth in claim 14 of producing a semiconductor wafer, wherein
in the step of annealing, the electromagnetic wave that has been pulsed is applied to the base wafer multiple times.

16. The method as set forth in claim 1 of producing a semiconductor wafer, wherein
the electromagnetic wave is applied from above the base wafer while heating is performed from below the portion to be thermally processed.

17. The method as set forth in claim 9 of producing a semiconductor wafer, wherein
in the step of annealing, the lattice defect density of the SiₓGe_{1-x crystal (}0≦x<1) is reduced to 10⁵ cm⁻² or lower.

18. The method as set forth in claim 1 of producing a semiconductor wafer, wherein
the step of forming a protective layer comprises forming, on the base wafer, an inhibition layer that inhibits a precursor of the portion to be thermally processed from growing into a crystal and protects the portion to be protected from the electromagnetic wave to be applied to the base wafer,
the method further comprises:
a step of forming, in the inhibition layer, an opening that penetrates the inhibition layer to the base wafer; and
a step of forming, as the portion to be thermally processed, a seed crystal within the opening, and
in the step of annealing, the seed crystal is also annealed by applying the electromagnetic wave.

19. The method as set forth in claim 18 of producing a semiconductor wafer, wherein
the step of forming a protective layer comprises further forming, on the inhibition layer, a block layer that blocks at least part of the electromagnetic wave.

20. The method as set forth in claim 18 of producing a semiconductor wafer, further comprising, after the step of annealing, a step of forming, by crystal growth, a compound semiconductor that has a lattice match or a pseudo lattice match with the seed crystal.

21. The method as set forth in claim 20 of producing a semiconductor wafer, wherein
the seed crystal is a SiₓGe₁₋ₓ crystal (0≦x<1), and the compound semiconductor is a group III-V compound semiconductor.

22. The method as set forth in claim 1 of producing a semiconductor wafer, wherein
the protective layer has a higher reflectivity of the electromagnetic wave than the portion to be protected.

23. The method as set forth in claim 22 of producing a semiconductor wafer, wherein
the protective layer comprises:
a thermal conduction restraining layer that restrains thermal conduction; and
a block layer that has been disposed on the thermal conduction restraining layer and has a higher reflectivity of the electromagnetic wave than the thermal conduction restraining layer, and
the thermal conduction restraining layer has a lower thermal conductivity than the block layer.

24. The method as set forth in claim 23 of producing a semiconductor wafer, wherein
the thermal conduction restraining layer has a lower thermal conductivity than the portion to be protected.

25. The method as set forth in claim 23 of producing a semiconductor wafer, wherein
the thermal conduction restraining layer comprises any one of silicon oxide, silicon nitride, silicon oxynitride, aluminum oxide, and polyimide.

26. The method as set forth in claim 23 of producing a semiconductor wafer, wherein
the block layer comprises a reflective layer that reflects at least part of the electromagnetic wave.

27. The method as set forth in claim 23 of producing a semiconductor wafer, wherein
the block layer comprises a scattering layer that scatters at least part of the electromagnetic wave.

28. The method as set forth in claim 23 of producing a semiconductor wafer, wherein
the block layer comprises an absorptive layer that absorbs at least part of the electromagnetic wave.

29. The method as set forth in claim 28 of producing a semiconductor wafer, wherein
the absorptive layer has a higher absorption coefficient of the electromagnetic wave than the portion to be thermally processed.

30. The method as set forth in claim 1 of producing a semiconductor wafer, wherein
the base wafer is any one of a Si wafer, an SOI wafer, a Ge wafer, a GOI wafer, and a GaAs wafer.

31. A semiconductor wafer comprising:
a base wafer;
an electronic element that has been formed on the base wafer and has an active region;
a SiₓGe₁₋ₓ crystal (0≦x<1) disposed on the base wafer; and
a protective layer that covers the active region and protects the active region from an electromagnetic wave applied to the base wafer.

32. The semiconductor wafer as set forth in claim 31, further comprising an inhibition layer that has been formed on the electronic element and inhibits a precursor of the SiₓGe₁₋ₓ crystal from growing into a crystal and serves as the protective layer, wherein
the SiₓGe₁₋ₓ crystal (0≦x<1) is disposed within an opening that penetrates the inhibition layer to the base wafer.

33. The semiconductor wafer as set forth in claim 32, further comprising a block layer that has been disposed on the inhibition layer and blocks at least part of the electromagnetic wave.

34. A method of producing an electronic device having a first electronic element and a second electronic element, the method comprising:
a step of forming the first electronic element on a base wafer;
a step of forming a protective layer that protects the first electronic element from an electromagnetic wave to be applied to the base wafer;
a step of forming a SiₓGe₁₋ₓ crystal (0≦x<1) on the base wafer;
a step of annealing the SiₓGe₁₋ₓ crystal by applying the electromagnetic wave to the base wafer;
a step of forming, by crystal growth, a group III-V compound semiconductor that has a lattice match or a pseudo lattice match with the SiₓGe₁₋ₓ crystal; and
a step of forming, on the group III-V compound semiconductor, the second electronic element that is electrically connected to the first electronic element.

35. The method as set forth in claim 34 of producing an electronic device, further comprising:
a step of forming, so as to cover at least the first electronic element, an inhibition layer that inhibits a precursor of the SiₓGe₁₋ₓ crystal from growing into a crystal and protects the first electronic element from the electromagnetic wave;
a step of forming an opening in a region of the inhibition layer, the region being other than a region covering the first electronic element, the opening penetrating the inhibition layer to the base wafer; and
a step of forming the SiₓGe₁₋ₓ crystal within the opening by growing the precursor of the SiₓGe₁₋ₓ crystal into a crystal.

36. The method as set forth in claim 35 of producing an electronic device, further comprising a step of forming a block layer that blocks the electromagnetic wave on the region of the inhibition layer, the region covering the first electronic element.

37. The method as set forth in claim 34 of producing an electronic device, wherein
the first electronic element is an electronic element included in at least one circuit among a driving circuit for the second electronic element, a correction circuit for improving linearity of input and output characteristics of the second electronic element, and a protection circuit for an input stage of the second electronic element, and
the second electronic element is an electronic element included in at least one device among an analog electronic device, a light emitting device, and a light receiving device.

38. A reaction apparatus comprising:
a reaction chamber holding therein a base wafer having a portion to be thermally processed that has a single-crystal layer and is to be subjected to thermal processing and a portion to be protected that is to be protected from heat to be added during the thermal processing;
an irradiating section that applies an electromagnetic wave toward the main plane of the base wafer, the main plane having the portion to be protected and the portion to be thermally processed that are formed therein;
a heating section that heats the entire base wafer from a side of the back plane that is opposite to the main plane;
a heating temperature measuring section that measures a temperature of the base wafer;
a temperature measuring section that measures a temperature of the portion to be protected and a temperature of the portion to be thermally processed; and
a control section that controls the irradiating section and the heating section based on a result of the measurement performed by the heating temperature measuring section and a result of the measurement performed by the temperature measuring section.

39. The reaction apparatus as set forth in claim 38, wherein
the temperature measuring section measures the temperature of the portion to be protected and the temperature of the portion to be thermally processed based on radiant heat from the portion to be protected and radiant heat from the portion to be thermally processed.

40. The reaction apparatus as set forth in claim 38, wherein
the temperature measuring section sequentially measures the temperature of the portion to be protected and the temperature of the portion to be thermally processed.

41. The reaction apparatus as set forth in claim 38, wherein
the control section determines, based on the result of the measurement performed by the heating temperature measuring section, an application period during which the irradiating section applies the electromagnetic wave and a non-application period during which the irradiating section does not apply the electromagnetic wave.

42. The reaction apparatus as set forth in claim 38, further comprising a filter that has been disposed between the base wafer and the irradiating section and blocks a wavelength component of the electromagnetic wave at which the absorption coefficient in the portion to be protected is higher than the absorption coefficient in the portion to be thermally processed.

43. The reaction apparatus as set forth in claim 38, further comprising a gas supply section that supplies a source gas into the reaction chamber, wherein
a compound semiconductor is formed by crystal growth on the portion to be thermally processed, by reaction of the source gas within the reaction chamber.

44. The reaction apparatus as set forth in claim 43, wherein
the source gas has a lower temperature than the base wafer, and
the source gas cools the base wafer while the compound semiconductor is formed by crystal growth.
